(19) United States
(12) Patent Application Publication
(10) Pub. No.: US 2024/0095543 A1
(43) Pub. Date: Mar. 21, 2024

(54) RECONSTRUCTION OF INFORMATION STORED IN A DNA STROAGE SYSTEM

(71) Applicants: Technion Research & Development Foundation Limited, Haifa (IL); BAR-ILAN UNIVERSITY, Ramat Gan (IL)

(72) Inventors: Daniella Bar-Lev, Haifa (IL); Itai Orr, Ramat Gan (IL); Omer Sabary, Kiryat Atta (IL); Tuvi Etzion, Haifa (IL); Eitan Yaakobi, Telaviv (IL)

(73) Assignees: Technion Research & Development Foundation Limited, Haifa (IL); BAR-ILAN UNIVERSITY, Ramat Gan (IL)

(21) Appl. No.: 18/233,855

(22) Filed: Aug. 14, 2023

Related U.S. Application Data
(60) Provisional application No. 63/371,399, filed on Aug. 14, 2022.

(51) Int. Cl. G06N 3/123; G06F 30/27

(52) U.S. Cl. CPC G06N 3/123; G06F 30/27

(57) ABSTRACT

A method for estimating an information unit represented by DNA strands, the method includes (a) sequencing the DNA strands to provide noisy copies of an encoded version of the information unit; wherein the information unit comprises information unit elements; (b) neural network (NN) processing the multiple noisy copies by one or more NNs to provide a soft estimate of the encoded information unit; wherein the soft estimate comprises estimated encoded information unit elements and an encoded information unit elements estimated confidence parameter; and (c) decoding the soft estimate of the encoded information unit to provide a prediction of the information unit.

### CROSS REFERENCE

This application claims priority from U.S. provisional patent Ser. No. 63/371,399 filing date Aug. 14, 2022 which is incorporated herein by reference.

### BACKGROUND

A DNA molecule consists of four building blocks called nucleotides: Adenine(A), Cytosine(C), Guanine(G) and Thymine(T). A single DNA strand, also called oligonucleotide, is an ordered sequence of some combination of these nucleotides and can be abstracted as a string over the alphabet {A, C, G, T}. The ability to chemically synthesize almost any possible nucleotides sequence makes it possible to store digital data on DNA strands. A DNA storage system is composed of three important entities—DNA synthesizer, storage container and a DNA sequencer.

DNA synthesizer—the synthesizer produces the strands that encode the data to be stored in DNA. It should be note that the current synthesis technologies cannot produce one single copy per strands, but only multiple copies. Moreover, the length of the strands produced by the synthesizer is typically bounded by roughly 200-300 nucleotides in order to sustain an acceptable error rate.

Storage container—a container with compartments that stores the DNA strands in an unordered manner.

DNA sequencer—the sequencer reads back the strands and transfers them back to digital data.

### Summary

### BRIEF DESCRIPTION OF THE DRAWINGS

The embodiments of the disclosure will be understood and appreciated more fully from the following detailed description, taken in conjunction with the drawings in which the various figures illustrate examples of processes, systems, encoding, decoding and results.

FIG. 1 illustrates an example of a DNA storage system;

FIG. 2 illustrates an example of a wrong prediction analysis;

FIG. 3 illustrates an example of a wrong prediction analysis;

FIG. 4 illustrates an example of a prediction analysis;

FIG. 5 illustrates an example of a wrong prediction analysis;

FIG. 6 illustrates an example of a prediction analysis;

FIG. 7 illustrates an example of a pre-processing noisy copies that precedes a deep neural network processing;

FIG. 8 illustrates an example of an DNA former architecture;

FIG. 9 illustrates an example of a method for writing to a DNA storage and reconstructing the data stored in the DNA storage;

FIG. 10 illustrates an example of the performance of the method;

FIG. 11 illustrates an example of the performance of the method;

FIG. 12 illustrates an example of DNAformer reconstruction;

FIG. 13 illustrates an example of DNAformer reconstruction;

FIG. 14 illustrates an example of the performance of the method;

FIG. 15 illustrates an example of an error correction scheme;

FIGS. 16-24 illustrate an example of a tensor-product encoding;

FIG. 25 illustrates an example of a DNN confidence for error detection;

FIGS. 26-30 illustrate an example of a tensor-product encoding;

FIG. 31 illustrates an example a method;

FIG. 32 illustrates an example a method; and

FIG. 33 illustrates an example a method.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a device or system capable of executing the method and/or to a non-transitory computer readable medium that stores instructions for executing the method.

Any reference in the specification to a system or device should be applied mutatis mutandis to a method that may be executed by the system, and/or may be applied mutatis mutandis to non-transitory computer readable medium that stores instructions executable by the system.

Any reference in the specification to a non-transitory computer readable medium should be applied mutatis mutandis to a device or system capable of executing instructions stored in the non-transitory computer readable medium and/or may be applied mutatis mutandis to a method for executing the instructions.

Any combination of any module or unit listed in any of the figures, any part of the specification and/or any claims may be provided.

The specification and/or drawings may refer to a processor. The processor may be a processing circuitry. The processing circuitry may be implemented as a central processing unit (CPU), and/or one or more other integrated circuits such as application-specific integrated circuits (ASICs), field programmable gate arrays (FPGAs), full-custom integrated circuits, etc., or a combination of such integrated circuits.

Any combination of any steps of any method illustrated in the specification and/or drawings may be provided.

Any combination of any subject matter of any of claims may be provided.

Any combinations of systems, units, components, processors, sensors, illustrated in the specification and/or drawings may be provided.

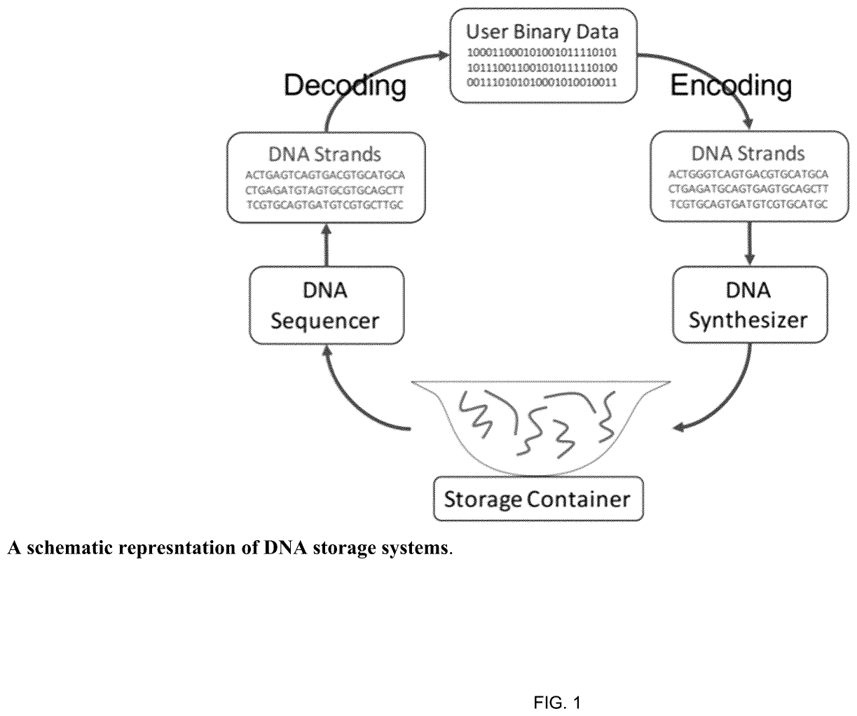

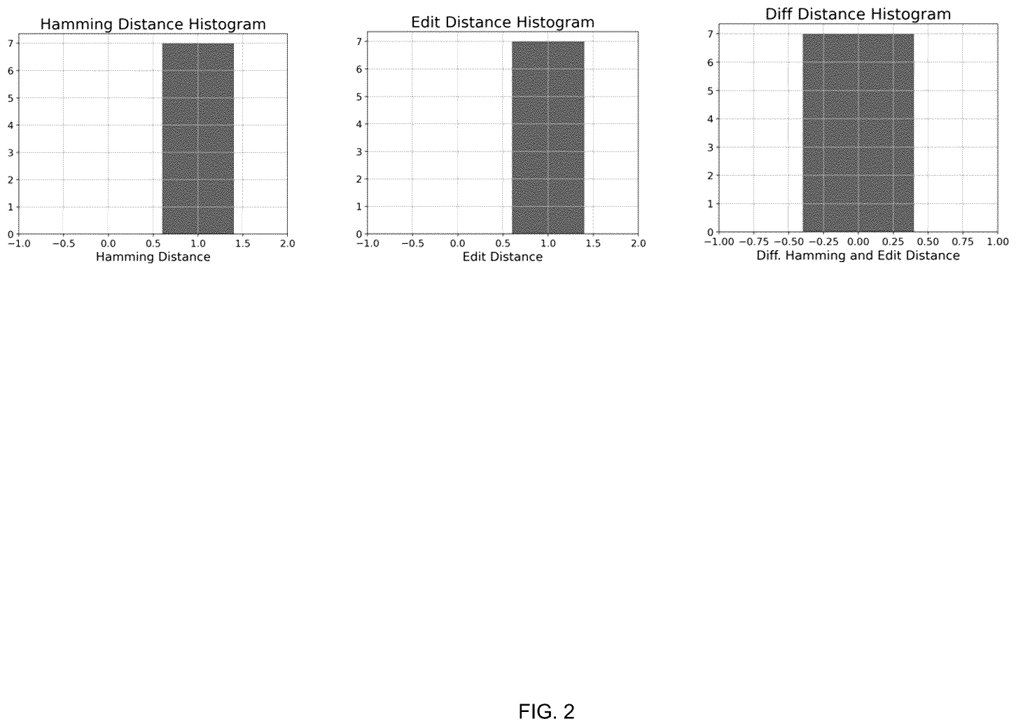

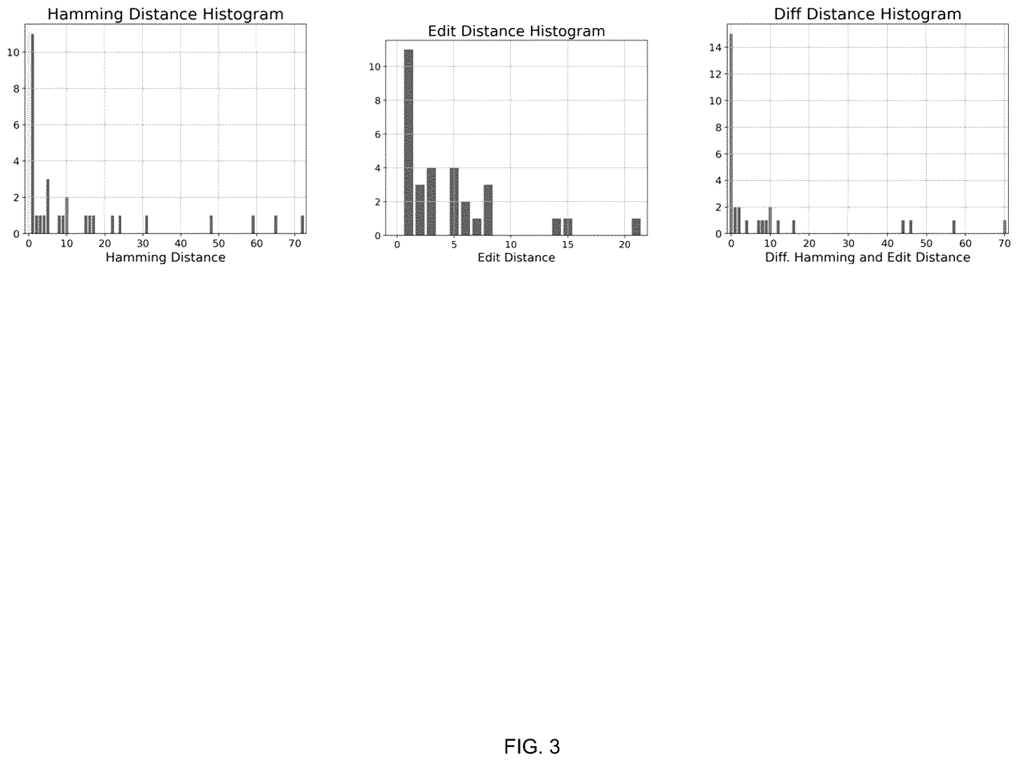

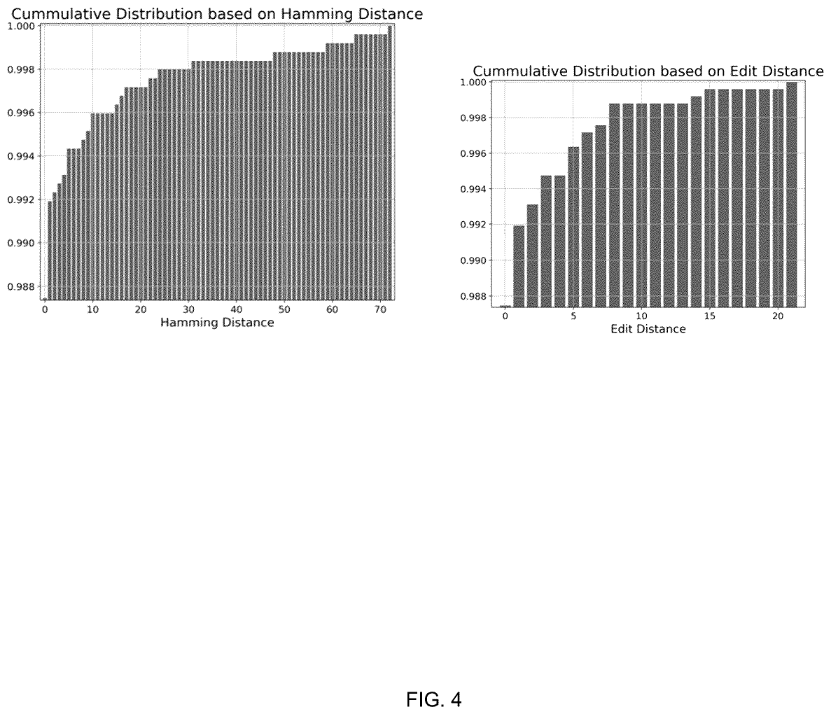

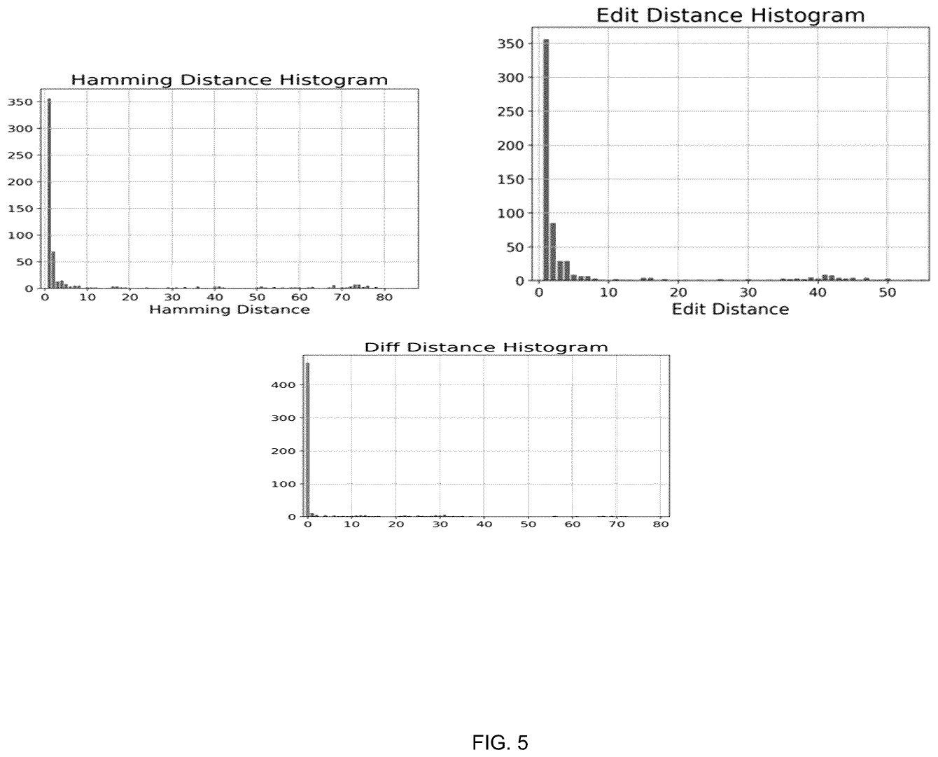

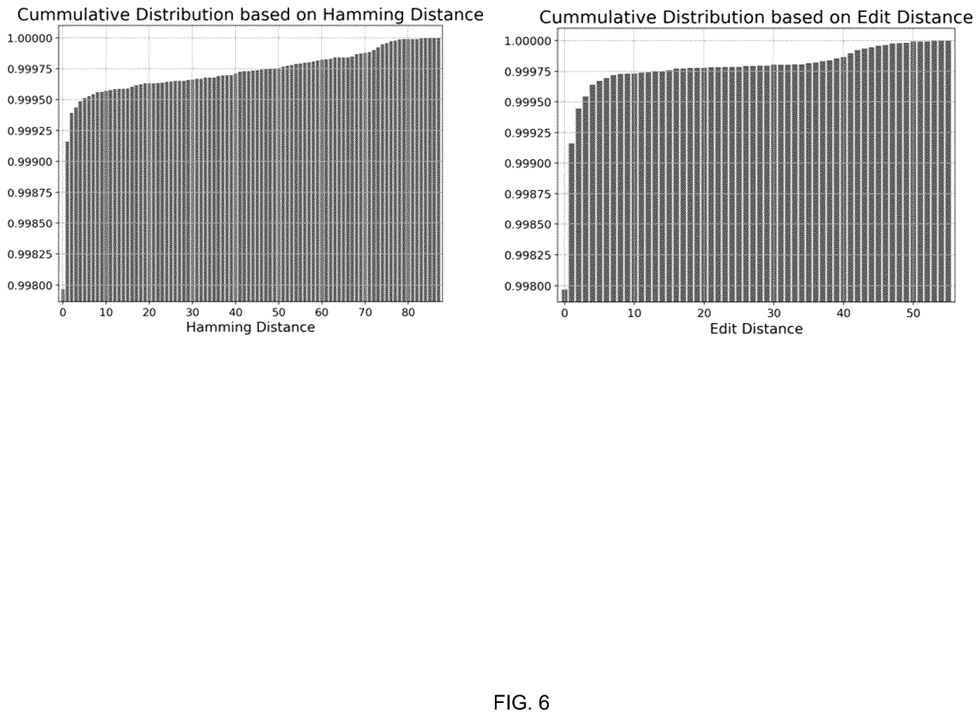

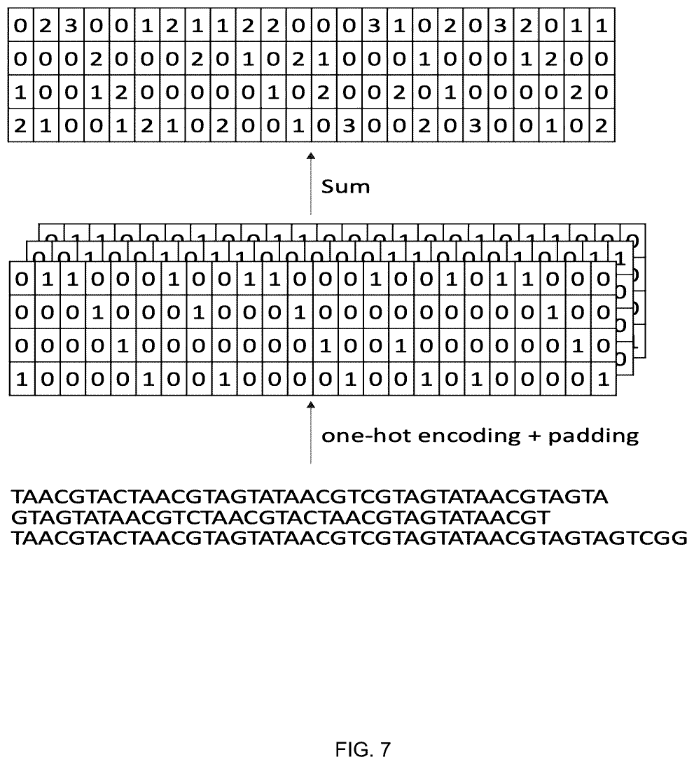

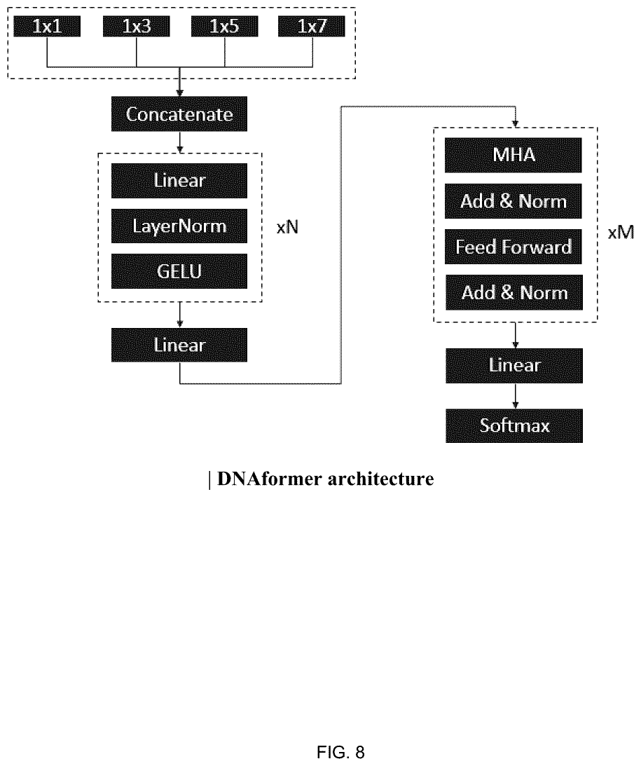

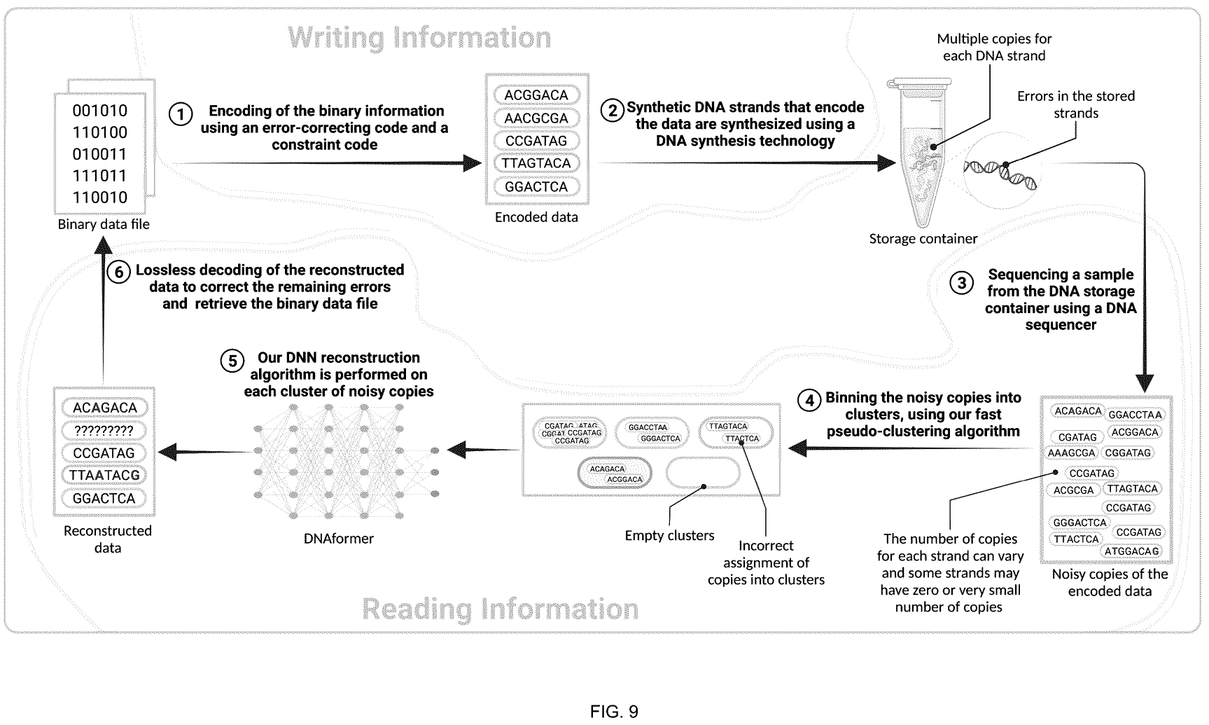

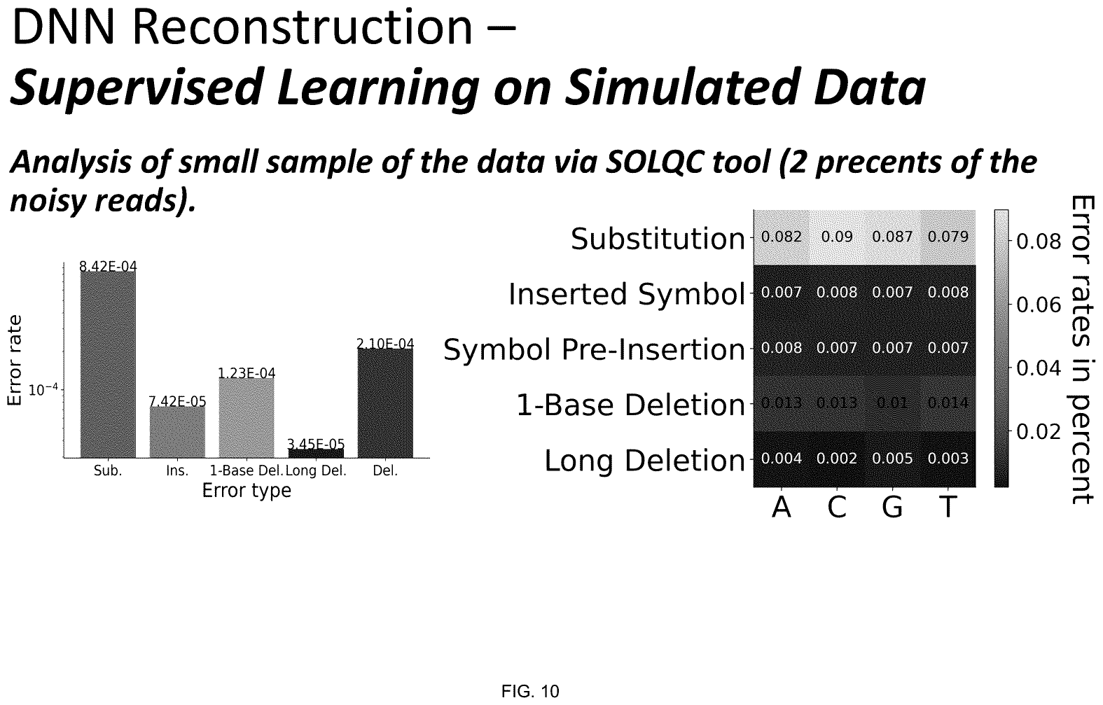

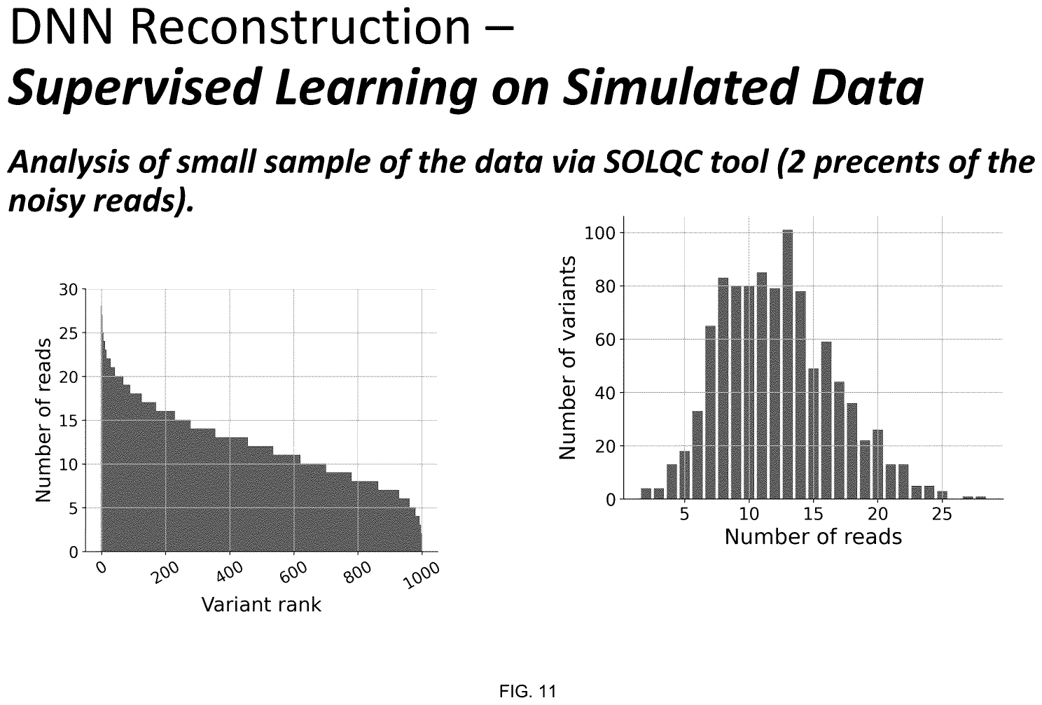

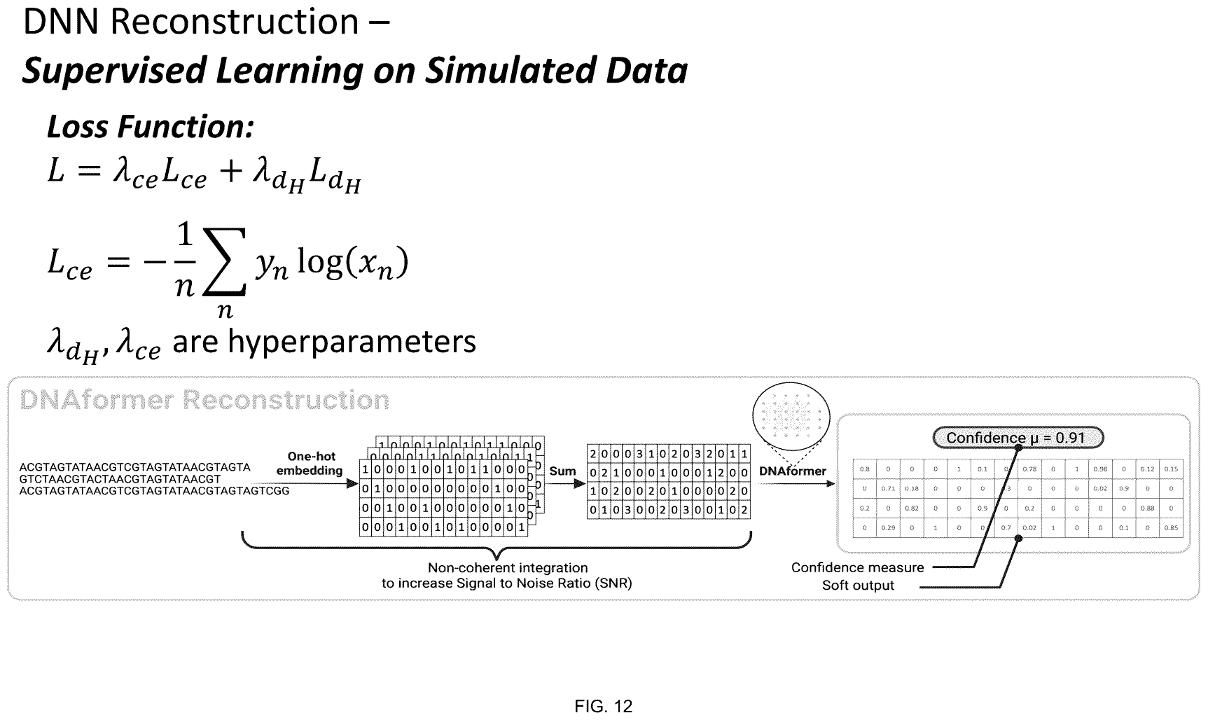

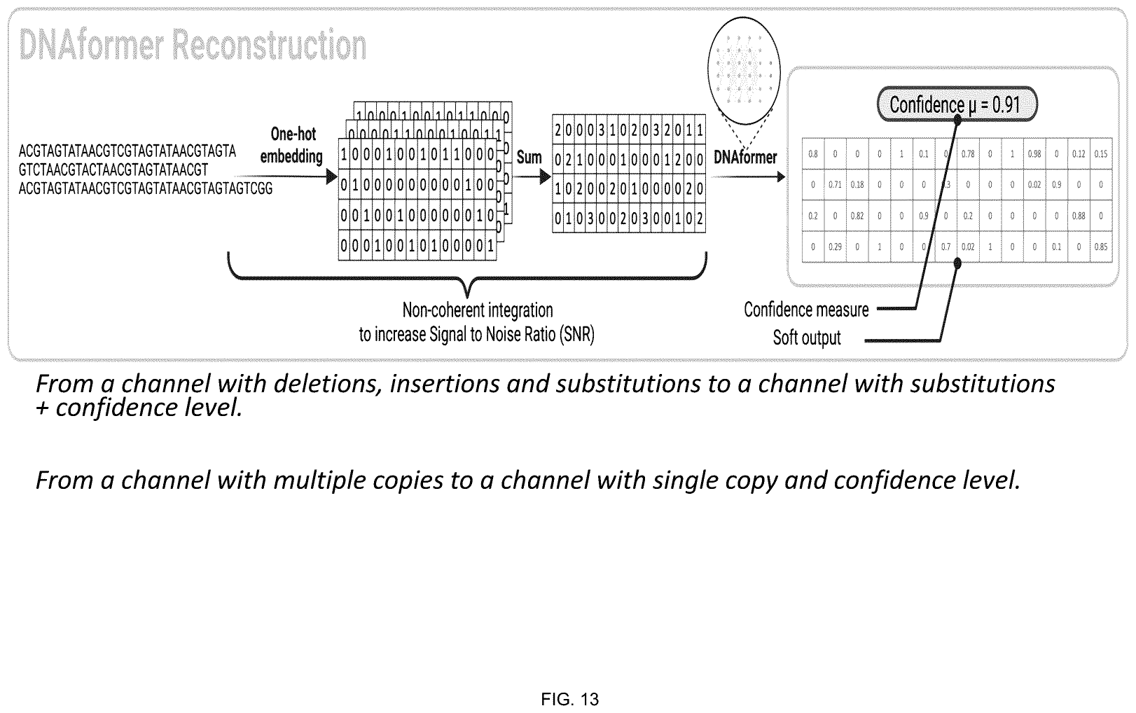

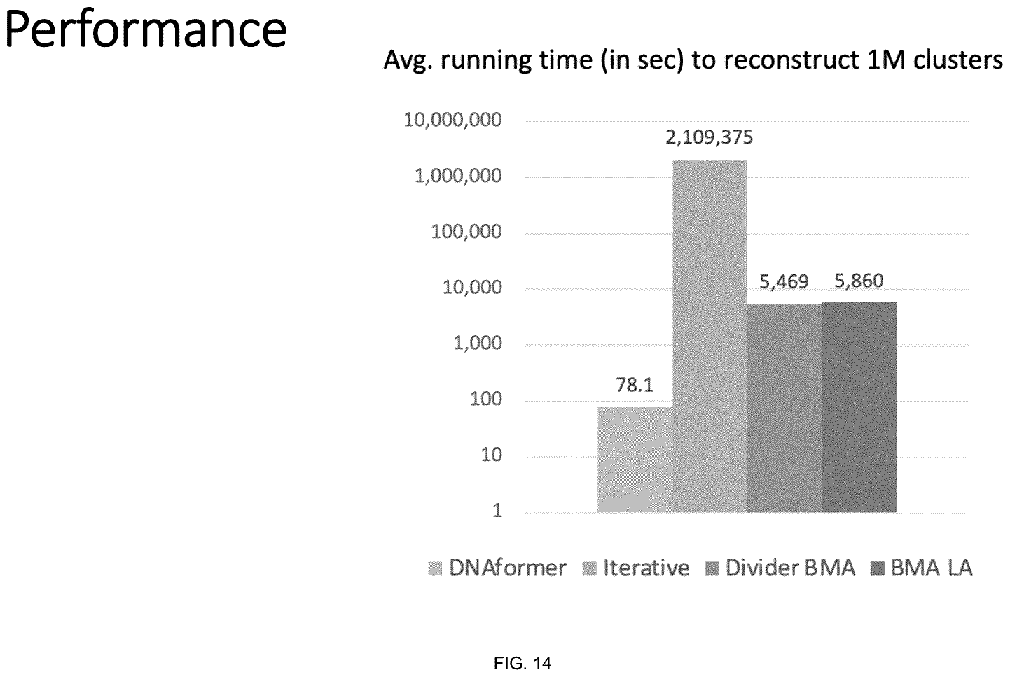

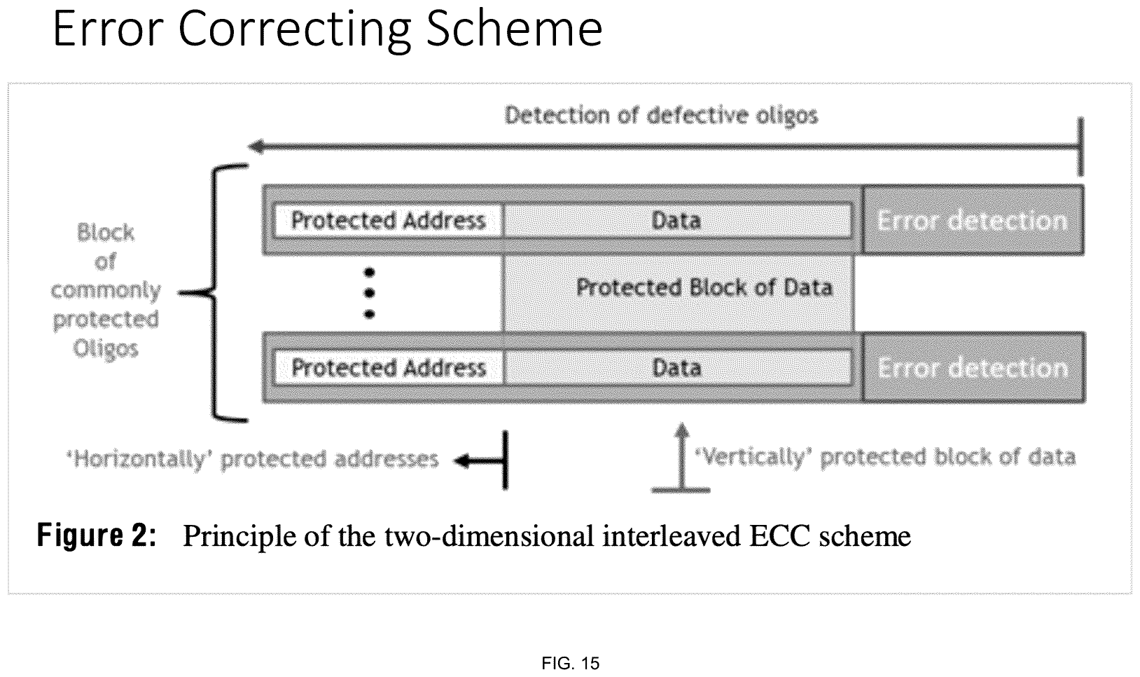

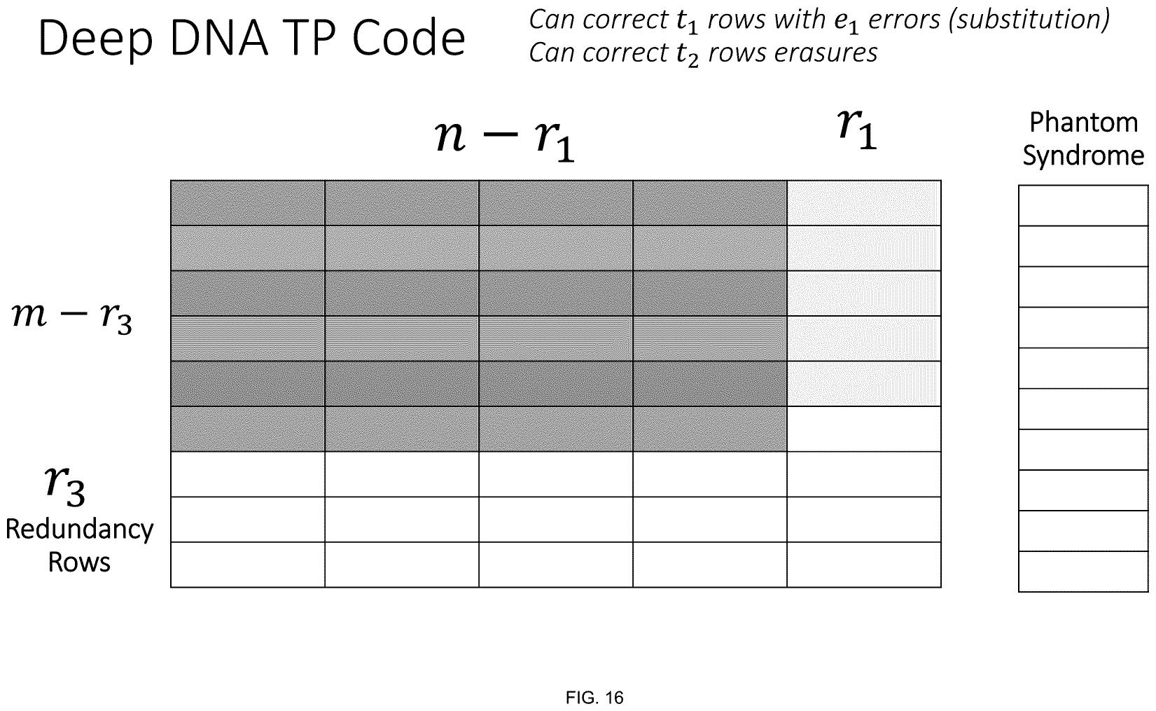

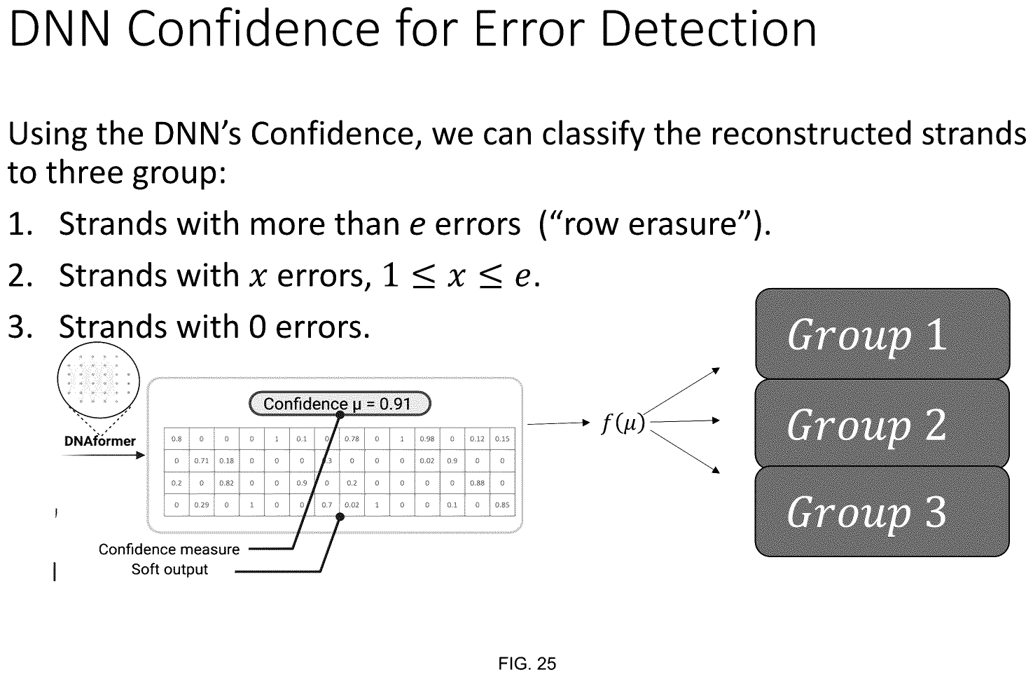

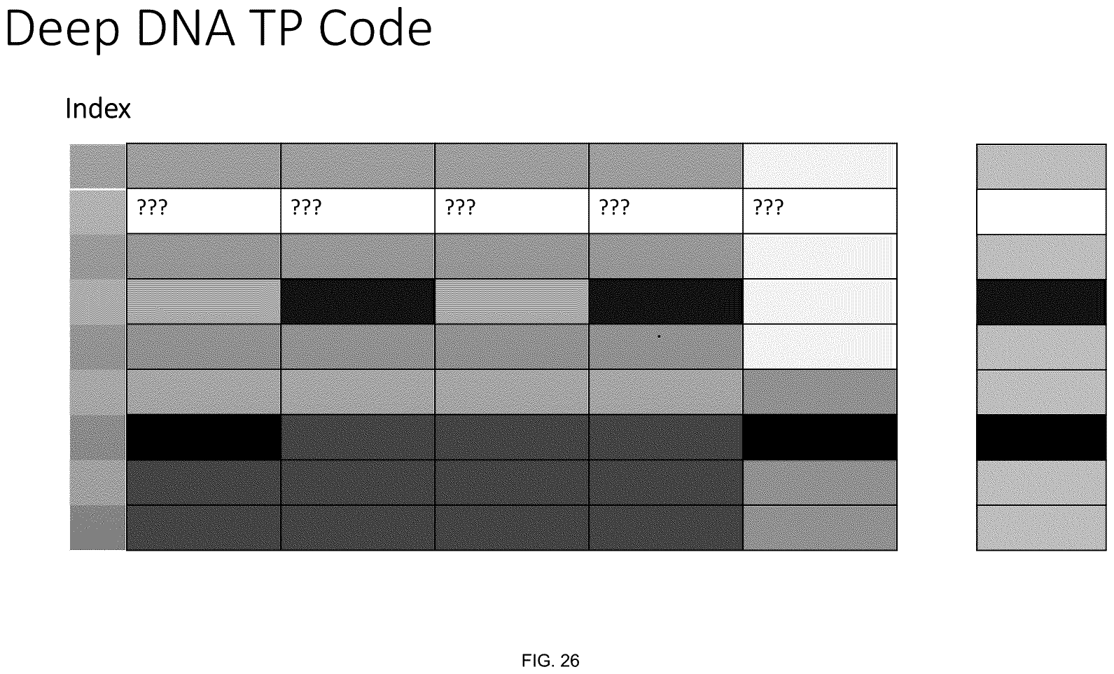

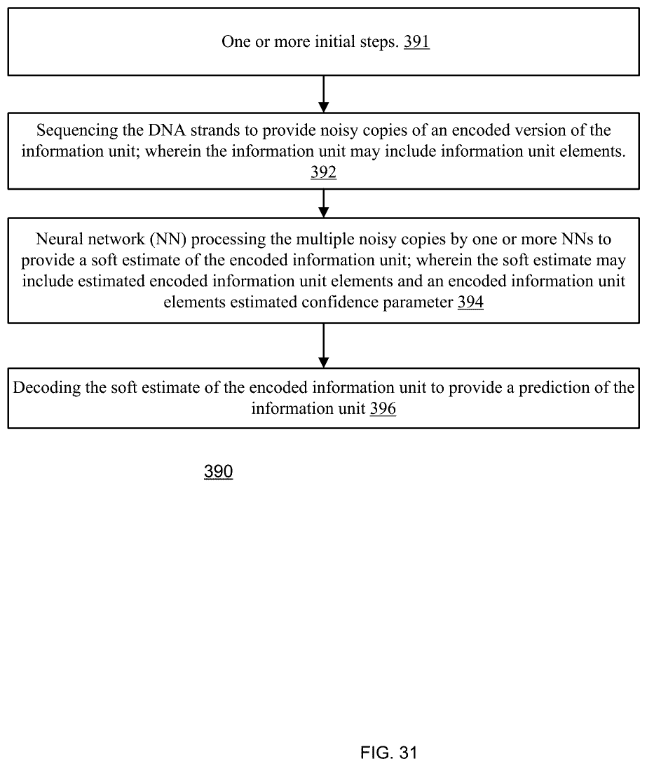

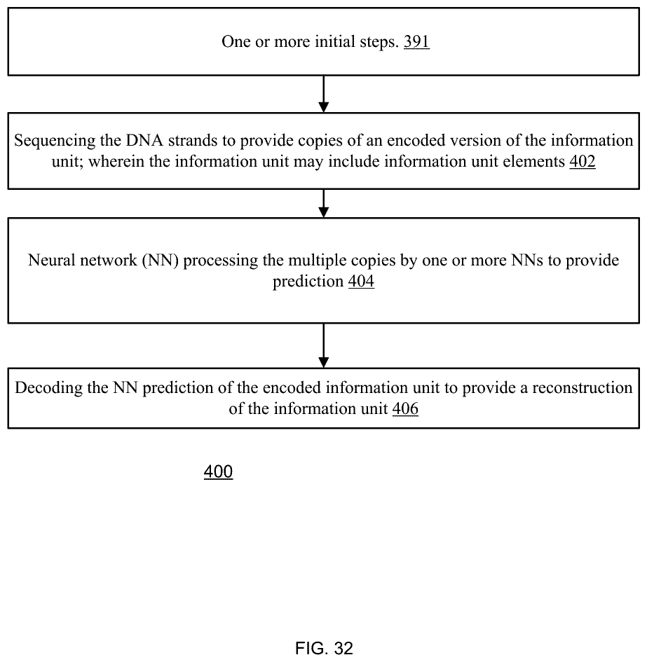

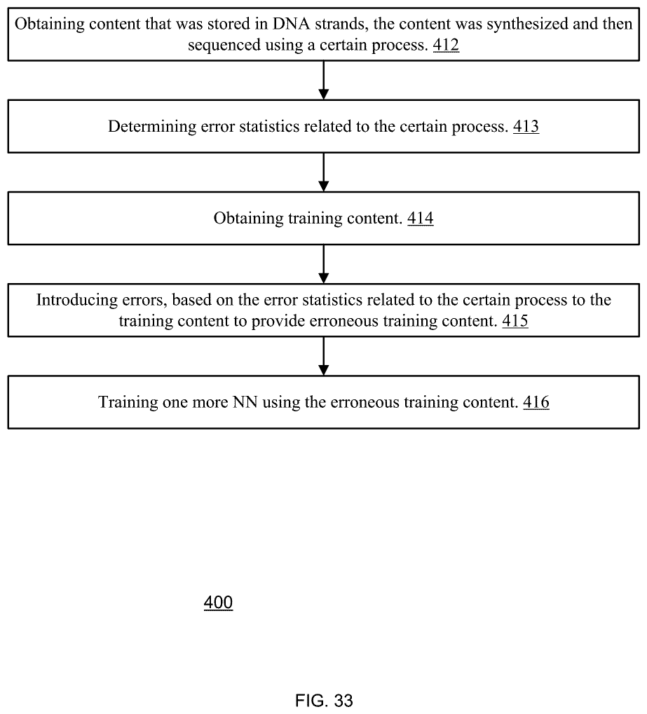

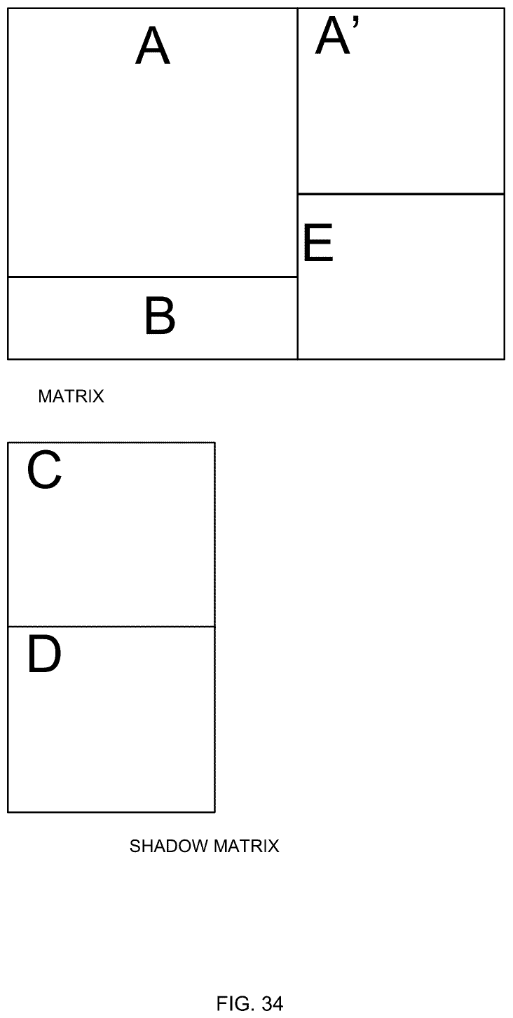

FIG. 1 illustrates an example of a DNA storage system. FIG. 2 illustrates an example of a wrong prediction analysis. FIG. 3 illustrates an example of a wrong prediction analysis. FIG. 4 illustrates an example of a prediction analysis. FIG. 5 illustrates an example of a wrong prediction analysis. FIG. 6 illustrates an example of a prediction analysis. FIG. 7 illustrates an example of a pre-processing noisy copies that precedes a deep neural network processing. FIG. 8 illustrates an example of an DNA former architecture. FIG. 9 illustrates an example of a method for writing to a DNA storage and reconstructing the data stored in the DNA storage. FIG. 10 illustrates an example of the performance of the method. FIG. 11 illustrates an example of the performance of the method. FIG. 12 illustrates an example of DNAformer reconstruction. FIG. 13 illustrates an example of DNAformer reconstruction. FIG. 14 illustrates an example of the performance of the method. FIG. 15 illustrates an example of an error correction scheme. FIGS. 16-24 illustrate an example of a tensor-product encoding. FIG. 25 illustrates an example of a DNN confidence for error detection. FIGS. 26-30 illustrate an example of a tensor-product encoding. FIG. 31 illustrates an example a method. FIG. 32 illustrates an example a method. FIG. 33 illustrates an example a method

DNA as a storage system has several attributes that differentiate it from any other storage system. The first is the inherent redundancy obtained by the synthesis and the sequencing processes, where each synthesized DNA strand has several copies. The second is that the strands are not ordered in the memory and thus it is not possible to know the order in which they were stored. The third attribute is the unique error behavior. Both the synthesis and the sequencing processes introduce errors to the synthesized DNA strands. The errors are mostly of three types, insertion, deletion, and substitution, where the error rates and their behavior depend on the synthesis and sequencing technologies. Since the synthesis and the sequencing processes are both error-prone, the conversion of the binary user data into strands of DNA could affect the data integrity. Therefore, to guarantee the ability to revert back to the original binary data of the user, ECC must be utilized.

The first large scale experiments that demonstrated the potential of in vitro DNA storage were reported by Church et al. who recovered 643 KB of data and Goldman et al.⁴ who accomplished the same task for a 739 KB message. However, both groups did not recover the entire message successfully due to the lack of usage in an appropriate coding solution to correct errors. Later, Grass et al. used a Reed Solomon based coding solution in their DNA storage experiment, where they stored and recovered successfully 81 KB message. In 2017, Erlich and Zielenski presented DNA Fountatin, a coding scheme that is based on Luby transform. In their experiment they stored and recovered 2.11 MB of data. Additionally, in 2017 Organick et al. developed and demonstrated a scheme that allows random access using DNA strands, where they stored 200 MB of data. Also In 2017, Yazdi et al. presented a new coding scheme that was designed to correct errors from Nanpore sequencers, which is a faster and cheaper sequencing technology that allows longer strands but has higher error rate. In their experiment they encoded 3.633 KB of data which was successfully recovered. Recently, Anavy et al. discovered that the capacity of the DNA storage can be increased using composite letters.

In a DNA storage system, all the noisy copies of the designed DNA sequences which contain the encoded data, are all being stored together, unordered, in one DNA tube. Hence, to retrieve the encoded data, a clustering algorithm should be applied on the data. In this clustering step, the unordered set of noisy copies from the tube is partitioned into clusters, where the goal is to partition the noisy copies into clusters such that all the copies in each cluster are originated from the same original designed DNA strand. Then, a reconstruction algorithm should be applied on each cluster to estimate the original designed strand from its noisy copies. The use of a clustering algorithm and then a reconstruction algorithm utilizes the inherent redundancy of DNA synthesis and sequencing to correct most of the errors. Then, if an ECC is applied on the designed DNA strands, the remaining errors can be corrected using a decoding procedure for the ECC.

In the DNA reconstruction problem, the goal is to estimate a sequence (with zero or small error probability in the estimation), from a set of its noisy copies. One of the challenges in the DNA storage channel is that we do not necessarily have control on the size of a cluster, and it is very likely that this size is significantly smaller than the required minimum size that guarantees a unique decoding of the designed DNA strand. Under this setup, a sequence x (the designed DNA strand) is transmitted t times over the deletion-insertion-substitution channel and generates t noisy copies (the cluster). A DNA reconstruction algorithm is a mapping which receives the t noisy copies as an input and produces \hat{x}, an estimation of x, and the target is to minimize the distance between x and \hat{x}.

In most of the previous DNA storage experiments the DNA reconstruction problem was not tackled directly for the following three reasons. First, the errors in DNA include deletions and insertions, which are known to be a challenging type of errors that are yet far from being solved optimally. Second, the clustering problem, which precedes the reconstruction problem is a challenging problem by itself. This is especially challenging when applied to DNA storage where the number of clusters can be extremely large. Third, most of the theoretical reconstruction algorithms, which were designed to address deletion and insertion errors, assumed that the clusters were partitioned (almost) perfectly, or were designed to work on a large block-length. Instead, in most of these previous experiments, the coding technique used redundant symbols which were added to each designed DNA strand (inner coding), or redundant DNA strands that were added (outer coding) in order to detect and correct the deletions and insertions errors. In these techniques, the clustering and the reconstruction steps can be avoided. However, the inherent redundancy of the DNA synthesis and sequencing was not utilized and hence the system has some wasted redundancy. In a parallel work, Nahum et al. proposed a single-strand reconstruction method, which is suitable for text files and image files and is based on an encoder-decoder transformers architecture.

In the current work, we present an end-to-end practical solution to the DNA reconstruction problem, which is resilient to clustering errors, and therefore allows us to use a simple and efficient pseudo-clustering algorithm effectively making our method a scalable solution for DNA storage. Our results on the noisy clusters are competitive to state-of-the-art reconstruction algorithms when the latter are evaluated on perfect clusters. In addition, our solution demonstrates a significant improvement in run-time performance, compared to previously published algorithms.

Our solution is based on DNN trained with simulated data to overcome errors originating from the synthesis and sequencing processes as well as the clustering step. The model, termed DNAformer, uses a combination of convolutions and transformers to reconstruct a sequence of letters based on a non-fixed number of varying lengths of noisy copies generated in the synthesis and sequencing processes. Our training methodology uses a small amount of real data to model the errors during the synthesis and sequencing processes. The error rates analysis and characterization were done using the SOLQC tool and once these errors are modeled, simulated data can be generated to train a DNN in any quantity required. The Simulated Data Generator (SDG) is based on the DNA storage simulator where the error injection module was adapted to increase the performance of the DNN. An important distinguishing property of this methodology is that the errors need to be modeled only once for each synthesis and sequencing processes, which makes our method scalable and cost effective.

A comparison of our method to current state-of-the-art results is provided in Table 1, where DNAformer achieves competitive results in comparison to previous reported methods. This performance is achieved even though our results are reported for imperfect clusters, based on our pseudo clustering method, while previous methods utilize near-perfect clustering, unattainable in a real-world data-storing application. Another three promising reconstruction algorithms were presented by Yazdi et al. and by Srinivasavaradhan et al. The first was designed by Yazdi et al. for their coding scheme to correct errors caused by Nanopore sequencers, therefore it relies on some coding constraints (such as exactly 50% of GC-content). It should be noted that these constraints are not satisfied in our tested datasets. In the second work by Srinivasavaradhan et al., two algorithms were presented, both of them are based on trellises that model the noisy copies and their probabilities and allow efficient method to compute and return the sequence that maximizes the posterior probability. To the best of our knowledge there is no available implementation of these two algorithms. A future research should compare our method with these algorithms. A Similar approach to one presented by Srinivasavaradhan et al. was also studied by Lenz et al.

The results show that our method achieves a failure rate of 0.02%, 1.3%, and 0.23% on the datasets provided by Erlich et al., Grass et al., and Organick et al., respectively. In all the datasets DNAformer achieves an inference time of about 10 ms per batch of 128 clusters, each containing up to 32 noisy copies; making it a highly scalable method for real-world applications of DNA storage.

Our method utilized simulated data only during training, meaning, we did not use real-data during the training of the models. The models were separately trained until convergence, on each dataset errors distribution. Training took 10 epochs with 1.5M clusters in each epoch with the same initial conditions, fixed seed, loss function, and hyper-parameters. Further details on the data modelling and generation, model architecture and training can be found in the ‘Methods’ section.

TABLE 1
Performance comparison to state-of-the-art methods. Our method
achieves a failure rate of 0.02%, 1.3%, and 0.23% on Erlich et al.,
Grass et al.,. and Organick et al. datasets, respectively, with an
inference time of 10 ms per batch of clusters.

| | | | Erlich | Grass | Organick |
|---|---|---|---|---|---|
| | | Clustering | et al. | et al. | et al. |
| Failure | DNAformer | Pseudo | 0.02% | 0.7% | 0.17% |
| rate | (our) | | 0.02% | 0.8% | 0.26% |
| | Iterative | Near- | | | |
| | Recon. | perfect | | | |
| | BMA | Near- | 0.02% | 1% | 0.233% |
| | Look Ahead | perfect | | | |
| | Divider | Near- | 0.02% | 1.75% | 0.24% |
| | BMA | perfect | | | |
| Inference | DNAformer | Pseudo | | 0.01 s/batch | |
| time | (our) | | | | |
| | Iterative | Near- | | 270 s/batch | |
| | Recon. | perfect | | | |
| | BMA | Near- | | 0.75 s/batch | |
| | Look Ahead | perfect | | | |
| | Divider | Near- | | 0.7 s/batch | |
| | BMA | perfect | | | |

Our DNAformer can run on a one or more processing circuits such as one or more CPUs (Central Processing Unit) and/or one or more GPUs (Graphics Processing Unit), while the other algorithms were designed to work only on a CPU. Additionally, the results of the suggested algorithm represent the evaluation of DNN reconstruction on noisy clusters that were obtained using our pseudo-clustering algorithm. The results of the other algorithms represent evaluation of the given algorithms on almost perfect clusters, which were obtained by matching each noisy copy to the closest designed sequence. It should be noted that this is not a realistic scenario since in actual storage systems the designed sequences are not given. Future research should compare the algorithms on the same input clusters, for perfect clusters, for clusters obtained by existing clustering algorithms, and for noisy clusters obtained by our pseudo-clustering.

Since our data generation method used the publicly available datasets to model the synthesis and sequencing errors, it is important to verify that there is no case of overfitting when reporting the results on these datasets. To verify this issue, we randomly split each dataset in half. One half of each dataset was used to generate the error statistics for our SDG and the other half was used for evaluation. In other words, the evaluation was performed on un-modelled data.

The results of this examination are presented in Table 2, where we report a good fit between the evaluation on the full and split datasets, thereby supporting the results reported in Table 1.

TABLE 2
Performance comparison between full and split datasets. The results show a good fit
between the full and split dataset cases. The split dataset case uses half of the data to generate
error statistics for the SDG and evaluates the other half of un-modelled data.

| | Erlich et al. | | Grass et al. | | Organick et al. | |
|---|---|---|---|---|---|---|
| Dataset | Full | Split | Full | Split | Full | Split |
| Synthesis | Twist Bioscience | | CustomArray | | Twist Bioscience | |
| Sequencing | Ilumina miSeq | | Ilumina miSeq | | Ilumina NextSeq | |
| Dataset size | 72,000 | 36,001 | 4,989 | 2,495 | 596,499 | 298,249 |
| Number of wrong | 16 | 7 | 64 | 31 | 1,373 | 630 |
| predictions* | | | | | | |
| Error percentage | 0.02% | 0.019% | 1.3% | 1.25% | 0.23% | 0.21% |

*Wrong prediction is defined as having at least one wrong character out of the entire predicted sequence.

Assessing the quality of our SDG was performed using the dataset provided by Organick et al. due to its relatively large size. The results are provided in Table 3 where we examined four data configurations. All configurations used the same model, hyperparameters, training settings and were trained for 10 epochs until convergence. To create the evaluation, the dataset was split into 425,006 frames for validation and 141,668 frames were used to model the error statistics and were also used to train the ‘Real data’ configuration. The ‘SDG’ configuration used 1.5M clusters per epoch. The ‘label+SDG’ configuration used real DNA designed strands as labels and generated simulated copies at each iteration. The ‘mixed real and simulated data’ configuration utilized a linear, progressive blending between the two data sources, which started with simulated data only in the first epoch and ended with real data only in the last epoch. The results show that utilizing our SDG can not only replace real data, which is expensive and time consuming to acquire, but also improve performance, largely due to the un-limited amount of simulated data that can be generated. Furthermore, the results show a small improvement when combining between a small amount of real data and a large amount (×10) of simulated data.

TABLE 3
Comparison between real and simulated data performance.
The results show the proposed SDG achieves better
performance than real data-based training. The combination of
real and simulated data achieved the best performance.

| | | Labels + | | Mixed real and |
|---|---|---|---|---|
| | SDG | SDG | Real data | simulated data |
| Number of wrong | 988 | 1155 | 1460 | 948 |
| predictions* | | | | |
| Failure rate | 0.23% | 0.27% | 0.34% | 0.22% |

Wrong prediction is defined as having at least one wrong character out of the entire predicted sequence.

When considering the whole data recovery process, we can distinguish between two types of errors in the sequence level (consider whether the prediction is correct or not for each cluster):
Missing clusters—when we do not sample noisy copies of some cluster or when we do sample noisy copies but misclassified them during our pseudo clustering step.
Wrong predictions—when the DNN prediction is not equal to the (original) designed DNA strand.

TABLE 4
Missing clusters and wrong prediction analysis. The evaluation was
performed on the split datasets, where the training configuration was
‘SDG’.

| | Erlich et al. | Grass et al. | Organick et al. |
|---|---|---|---|
| Number of tested clusters | 35,999 | 2,495 | 298,249 |
| Missing clusters* | 0 | 1 | 5,325 |
| Number of empty | 10 | 20 | 127 |
| clusters due to | | | |
| wrong pseudo-clustering | | | |
| Wrong predictions | 7 | 31 | 606 |
| Success rate from | 99.95% | 97.95% | 99.75% |
| existing clusters | | | |
| Total success rate | 99.95% | 97.91% | 97.97% |

The tested clusters were drawn randomly from the set of non-empty clusters such that half of them is selected. Therefore, the number of missing clusters is estimated to be half of the number of missing clusters in the entire data set.

Lastly, for each divided dataset we analyzed the errors within any wrong prediction (see FIGS. 3-6). For each wrong prediction we considered the Hamming distance and the edit distance between the prediction and the corresponding designed DNA strand. The Hamming distance between two sequences with the same length is defined to be the number of locations where the two sequences are different, i.e., the sequences have different letters on these locations. The edit distance between two sequences is defined to be the required minimum number of insertions, deletions, and letter substitutions operations to transform one sequence to the other. We also considered the difference between the Hamming and the edit distances for each wrong prediction.

### DISCUSSION

The conventional way to address missing clusters is by applying an outer ECC (for substitutions or erasures) on the clusters, that is, adding some redundant clusters in order to retrieve the missing ones. In addition, since deletions and insertions are hard to handle, in most of the previous works, there was no effort to correct the wrong predictions. Instead, these were considered as substitutions in the outer code; codes with enough redundant clusters were used in order to overcome both missing clusters and wrong predictions.

Nevertheless, when considering the errors within wrong predictions obtained by our solution and presented in FIGS. 3-6, we see that most of the wrong predictions suffer only a small number of substitution errors (and no insertion or deletion errors). Hence, an inner ECC, that can correct up to e substitutions (for some parameter e) can be used within each cluster in order to correct these substitutions. Using such an inner code, the majority of the correctly designed DNA strands can be retrieved from the corresponding wrong predictions. Future research should design new coding schemes that can utilize this error behavior to use less redundancy symbols while maintaining the same data integrity. A promising candidate for such schemes is the family of tensor-product codes.

The results in FIGS. 3-6 suggest that in each of the tested datasets, even when the output of the reconstruction method is not accurate, in the majority of the wrong predictions we have only Hamming errors (in this case the Hamming and the edit distances are equal) and their number is significantly small.

Our solution is centered around a DNN to perform the DNA reconstruction. However, the current cost of producing a large volume of real data for training such a model is high. In addition, since there is a need to employ an ECC, each change in the design of the code will require a new dataset. For these reasons, we turn to simulated data to train our model.

Our training methodology uses a small amount of data from real experiments to model the errors and create an SDG from which we can create an unlimited amount of training data. In the current design, the coding scheme is decoupled from the model. This allows to easily adapt the model to any coding scheme. Future experiments should examine combining the two to create an end-to-end process. Whenever using simulated data for real-world applications, it is important to verify that the domain transfer (i.e., from simulated to real data) works well, as our experiments evidently show.

To overcome the runtime limitations of current DNA storage pipelines, while using the inherent redundancy of the DNA storage channel, our design uses a naïve and very efficient method for pseudo-clustering. However, this comes at a cost of noise within each cluster. Therefore, the DNA reconstruction algorithm needs to be able to handle this type of noise. DNN are a good fit for these requirements due to their parallel computational nature and GPU implementations, which allowed us to achieve inference time an order of magnitude faster than previous solutions.

The data embedding method used is adapted to fit a communication channel where the major source of errors is substitution. More specifically, we adapt the notion of ‘Non-Coherent Integration’ and use elementwise summation to increase the model confidence towards a specific letter at each index.

We suspect that in cases where the dominant errors are deletion or insertion the model architecture and data embedding should be adapted to better handle these types of errors.

Our model architecture combines a convolution-based, Xception styled encoder and a transformers backbone with an output length of the entire sequence. Further experiments should be conducted to examine the relationship between these parts and compared to additional baseline architectures.

In this work we present a scalable method for DNA storage which overcomes a main bottleneck in current solutions for balancing failure rate and run-time. Our method is centered around a DNN to reconstruct a sequence of letters based on imperfect but highly efficient and fast pseudo-clustering method using a cleaver ECC.

Our results showed that DNN can significantly improve the decoding process in DNA storage system, effectively shortening a DNA storage system response time by several orders of magnitude. From a broader perspective, our DNN-based approach allows to abstract the whole end-to-end solution as a simple substitution channel and neglect the original deletion and insertion types of errors. In future work, it will be interesting to understand how similar methods can be exploited to other and communication channels, and in particular, other synchronization channels.

One of the merits of DNA-based storage is high data density, meaning a scalable storage system needs to be able to quickly handle arbitrary large files. In order to create a scale-invariant method, our method does not require the entire file to be processed simultaneously and is designed to process data in smaller batches.

Hence, our solution can be adapted to random access purposes. In addition, our method can be easily implemented on a GPU for fast processing

Since the synthesized DNA strands are stored together unordered, the first step of our method is clustering. As mentioned above, one of the greatest advantages of our method, is that our reconstruction procedure does not require perfect clustering.

When the error rates of the synthesis and sequencing technologies are relatively small (less then 10% in total), we use a method termed ‘noisy prefix clustering’. Meaning, each noisy copy is clustered based on its prefix of length L which is of order log n where n is the number of clusters.

Our reconstruction algorithm uses a DNN which predicts a single label sequence from a cluster of noisy copies. Since the data is randomly sampled, each cluster can vary in size and each copy can vary in length as a result of the synthesis and sequencing processes. Moreover, some clusters can suffer from higher error rates compared to others.

Training and Simulated Data Generation

Designing a method which combines a DNN and ECC requires the ability to iterate between the two parts during the design phase. Meaning, the coding scheme and DNN are coupled together in order to guarantee a specific set of success metrics. However, creating a different dataset to be used for training for each coding scheme modification is a costly and resource intensive process. For example, using previous DNA storage systems, the estimated cost of synthesizing 1 GB of data is roughly $3-5 million.

Due to this fact, we turn to simulated data generation. The main challenge when using simulated data for training is the generalization of real-world data after the model is trained. To overcome this issue, we construct a data generator based on statistics from real-world experiments. These statistics contain the error probabilities which are used to generate the noisy copies of each label. Pseudo code for each iteration of training: (i) Draw a random sequence of letters (ACGT). (ii) Encode the sequence using some error-correcting scheme (optional). (iii) Draw a random number of noisy copies and a random number of false copies. (iv) Draw random deviation from modeled error probabilities. (v) Inject simulated errors for each copy. (vi) Batch several clusters. (vii) Train DNN: forward pass, loss calculation, backward pass and weights update.

Model—Data Embedding

Data embedding was designed to take advantage of the dominant errors present in the dataset. In the case of the examined processes, the dominant error type is substitution and not deletion or insertion. Meaning, in the case of multiple noisy copies, we can increase the signal to noise ratio of the entire cluster by using a simple summation per index. Performing the summation of the noisy copies can be viewed as a form of ‘non-coherent’ integration of a multi-channel noisy signal. Meaning, if there is an agreement between different copies at some index, its overall value will be larger. However, if there are different values at some index, all values will be recorded which will represent the noise and uncertainty at that index. The data embedding includes several steps: (i) Filtering long or short copies beyond a specified parameter. (ii) One hot encoding (iii) Padding of short copies to the label length+corrupt deviation length. Summing of the noisy copies During our experiments, a normalization step was also examined after the summation. However, this did not prove beneficial, suggesting the model utilizes the absolute number at each summed index as a measure of confidence at that location.

FIG. 7 illustrates the main steps involved in the data embedding scheme.

Due to ours termed DNAformer, uses a combination of convolutions and transformers. We adopt the concept of early convolutions before a transformer block to improve training stability and performance. The embedding module uses an Xception inspired architecture with depth wise separable convolutions and multiple kernel heads. The purpose of using multiple kernels in the embedding layer is to allow the model to capture different shifts caused by deletion or insertion errors. Note that due to the convolutions in the embedding module, there is no need for position embedding.

In addition, the embedding module outputs a sequence with the required output length and larger feature space. After the embedding module, a multi-head transformer architecture is used with Multi-Layer Perceptron (MLP) as feedforward layers. After the last transformer block, a linear module is used to reduce the number of features to 4 which represent one-hot encoding for DNA representation and a softmax to transform this representation to probabilities. The model architecture is illustrated in FIG. 8.

Loss Function

To train our model a combination of cross entropy and Hamming loss was used and are shown in Eq. (1), (2), and (3):

$$ℒ = {λ}_{ce} {ℒ}_{ce} + {λ}_{Hamming} {ℒ}_{Hamming} \qquad ( 1 )$$

$${ℒ}_{ce} = - \frac{1}{n} {\sum }_{n} {y}_{n} log ( {x}_{n} ) \qquad ( 2 )$$

$${ℒ}_{Hamming} = \frac{1}{n} {\sum }_{n} 1 ( {x}_{n} \neq {y}_{n} ) \qquad ( 3 )$$

Where λ_{ce}, λ_{Hamming} are hyperparameters.

Implementation Details

Data generation and training was implemented in Pytorch, optimizer used was Adam with β₁=0.9, β₂=0.999, batch size 128 and learning rate utilized cosine decay from 3.141·10⁻⁵ to 3.141·10⁻⁷. A single 2080Ti GPU was used during training and inference.

Coding and Encoding

In terms of coding theory, our presented solution allows to abstract the whole end-to-end reconstruction problem from synchronization channels as a simple substitution single-channel and neglect the original deletion and insertion types of errors. To the best of our knowledge, our solution is the first to suggest the use of the inherent redundancy and a deep learning method to simplify the errors of a given synchronization channel (or any other probabilistic channels) and thus to allow faster computation and decoding time, less redundancy, and simpler coding schemes. Utilizing the inherent redundancy of DNA storage systems allow us to use less redundancy symbols in the ECC.

While in most of the previously published work, they use an inner-outer code approach, that did not utilize the fact that the erroneous clusters are relatively small. In classic inner-outer code approaches there is an inner code that protects each strand that encodes the data from errors within its symbols, as well as outer code that protects an erasure of a strand.

By design, the DNN reconstruction eliminates most of the deletions and insertions, and the output has the same length as the correct result. Hence, after this step we need to only take care of substitution errors (this by itself is easier to solve and requires less redundancy).

The DNN output include confidence level, and from our previous analysis, the DNN predicted strands are partitioned into four sets (four classes):
Correct predictions—most of the clusters (roughly 85%-100%).
Missing clusters—can be corrected by the outer code easily (requires small redundancy).
Wrong predictions with small number of substitutions.
Wrong predictions with large number of substitutions.

In the standard inner-outer code method, each strand is encoded by itself using the inner code in order to identify/correct errors. Hence, using this approach, we can only set the threshold of the inner-code's error capability relatively high (to handle strands from the 4^{th} group) or set this threshold lower and overcome the errors in the 4^{th} group strands by increasing the redundancy of the outer code.

However, since the size of the 4^{th} group is very small (between 0% to 3% of the clusters), it is wasteful to encode each of the strands with an inner code that can correct many errors. Moreover, it is wasteful to encode each strand with inner code in general even for small number of errors as most of the strands are correct. Without additional information, there is not much gain that can be achieved here.

According to an embodiment—when finding the DNA predicted strands (of noisy copies of an encoded version of the information unit) having a low confidence level (below a predefined threshold) are found—a re-estimation process of the noisy copies of an encoded version of the information unit can be executed. The re-estimation may include passing the noisy copies of an encoded version of the information unit and the DNA predicted strands through the DNN. The re-estimation may utilize any other reconstruction process.

In our scheme, we use these observations to design a code which is tailor-made to the DNN outputs and consider the confidence parameter. The key point is that using the confidence parameter, we can classify the outputs from the 4^{th} group (with very high accuracy) and to ignore them, i.e. treat them as missing clusters. It should be noted that, tensor-product method could have been used without the confidence of the DNN, but in this case additional redundancy is required in a way that is like the inner-outer code method.

Encode:
(1) We create an empty matrix with four regions (A, A′ B, E, see above).
(2) The binary data is written into A and A′.
(3) The columns in region A are encoded with ECC that can correct erasures and substitutions, and the redundancy bits are written into B.
(4) Applying the constraint code on A, A′ and B. After this step the elements in the matrix are in quaternary alphabet {A,C,G,T}.
(5) A predefine matrix H, is used to calculate the region C by multiplying each of the first rows within our matrix (the number of rows is as the number of rows in A′) with the matrix H (e.g., if M_i is the i-th row of our matrix then C_i, the i-th row of region C is simply H*M_i).
(6) Encode region C with ECC (not the same one as in the step 3 of the encoding) that can correct erasures and substitutions.
(7) Region E is completed such that every row in matrix M satisfy that H*M_i=V_i, where M_i is the i-th row in matrix M, and V_i, is the i-th row in the matrix V (consists of region C and D).
The encoded word is the matrix consists of regions A, A′, B, and E.

It should be noted that in fact, the ECC in step (5) is performed on binary data. Hence, before this step the data is decoded to binary using our constraint code, then encoded with ECC and then encoded back with the constraint code.

Steps (5), (6) and (7) are tensor product code.

Constraint code: Our constraint code is based a predefined mapping function that takes k bits and translate them to s DNA bases. The set of allowed DNA sequences of length s consists of all the word of length s over A,C,G,T, which do not contain r identical consecutive symbols in the middle and r/2 identical consecutive symbols in the edges (which guarantee that concatenation of such words will never result with a sequence of r identical consecutive symbols).

This set is than partitioned to s+1 groups based on the number of occurrences of G or C symbols within them (from 0 to s GC content). For any binary input of length k, the mapping either translate the input to a sequence that belongs to the group with s/2 GC content (“balanced” GC words), or to a couple of sequences, such that one belongs to a group with GC content strictly lower than s/2 and the other has GC content strictly higher than s/2.

Note that the parameters are selected such that this mapping is reversable, i.e., each valid DNA sequence belongs to the image of no more than 1 binary word of length k.

The encoding works as follows:

Given a binary string (one row from the previous matrix) of length x*k, we encode the x blocks of length k iteratively as follows.
(a) GC counter is initialized with 0.
(b) In each step:
   If the block is mapped to a single balanced string, translate it to this string.
   Otherwise,
      i. If the counter is positive, select the sequence with less than s/2 GC content, and update the counter, such that it reflect the current GC content of the entire sequence. (In this step we decrease the GC content of the sequence).
      ii. Otherwise, select the sequence with more than s/2 GC content, and update the counter, such that it reflect the current GC content of the entire sequence. (In this step we increase the GC content of the sequence).

This method allows us to satisfy the two main constraint for DNA storage: limiting the runs length and maintain balance GC content of each strand. These constraints are results of sequencing and synthesis technology limitations.

This method allows us to maintain the GC-content constraint also locally within each strand, and not just globally. This property was not studied before in the context of DNA storage, and it might reduce the error rate of the PCR process. (We are currently conducting a wet experiment to examine this hypothesis).

Decoding can be performed in parallel to all the blocks since they are independent.

Since we encode each block separately and their decoding is independent, we can easily combine this scheme with our ECC code. Note that, in general, combining constraint code with ECC is known to be a challenging problem in coding theory.

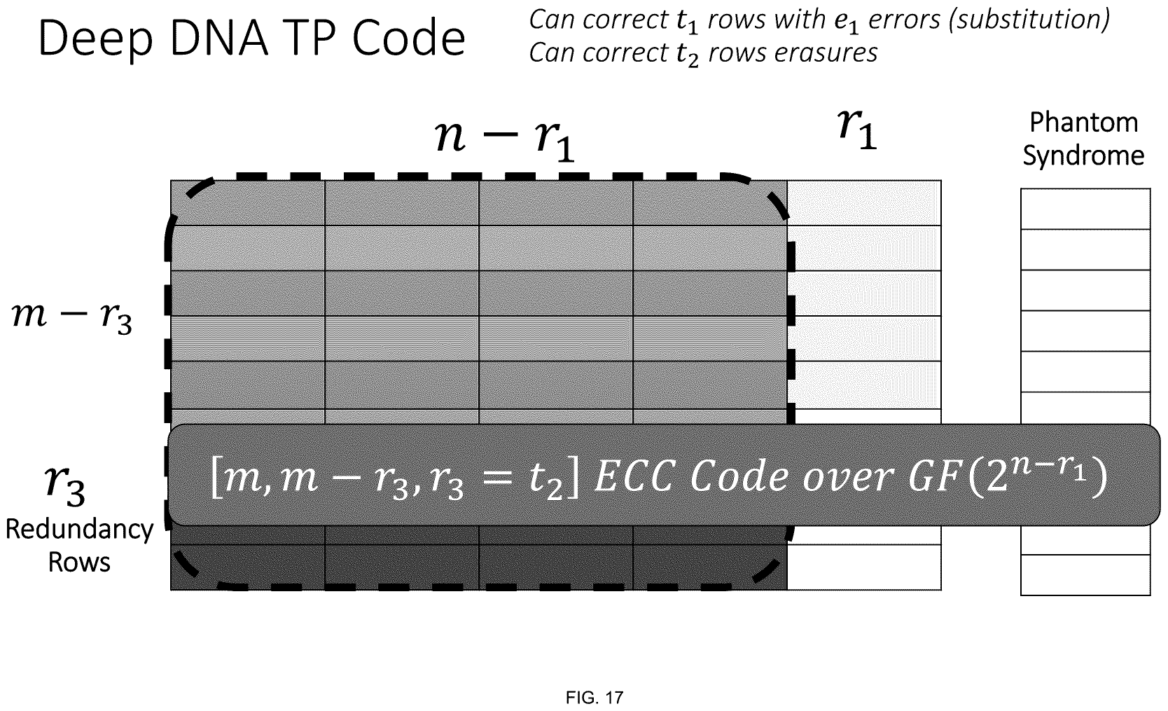

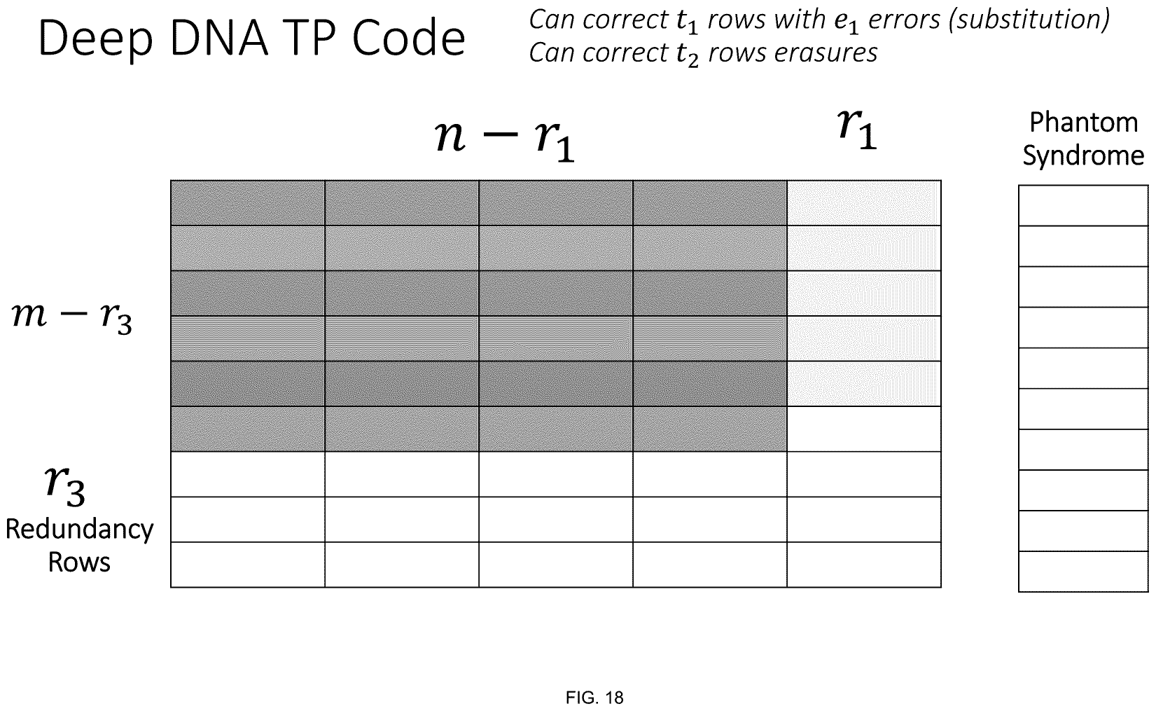

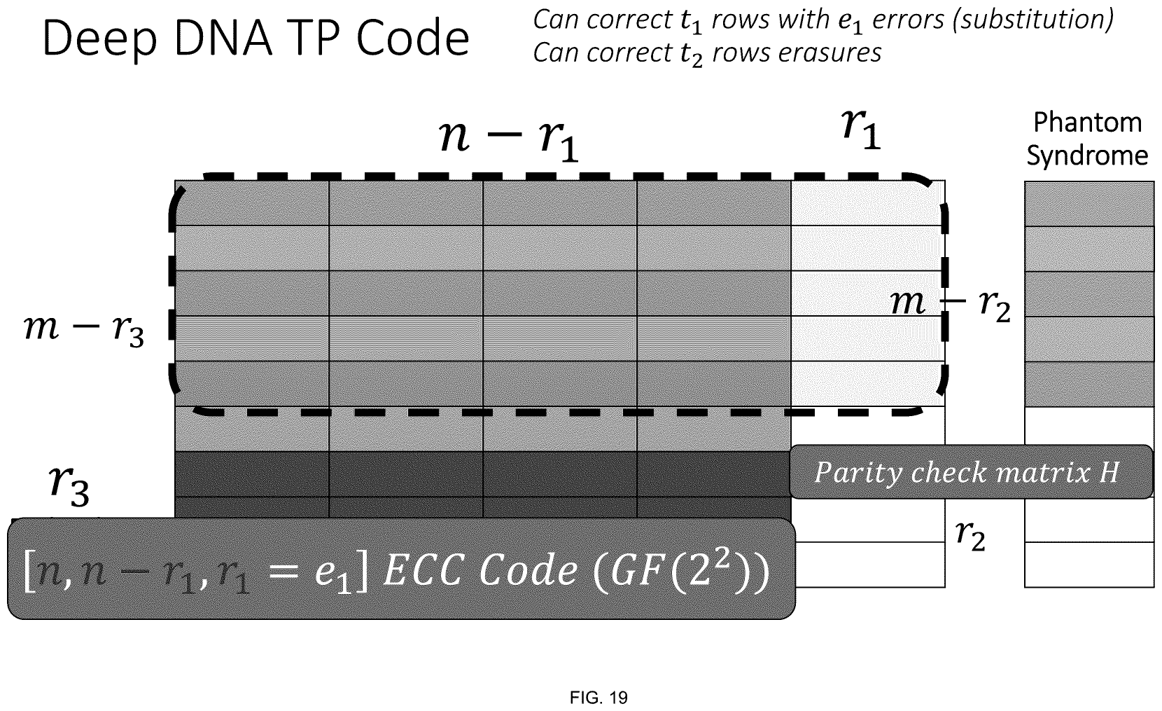

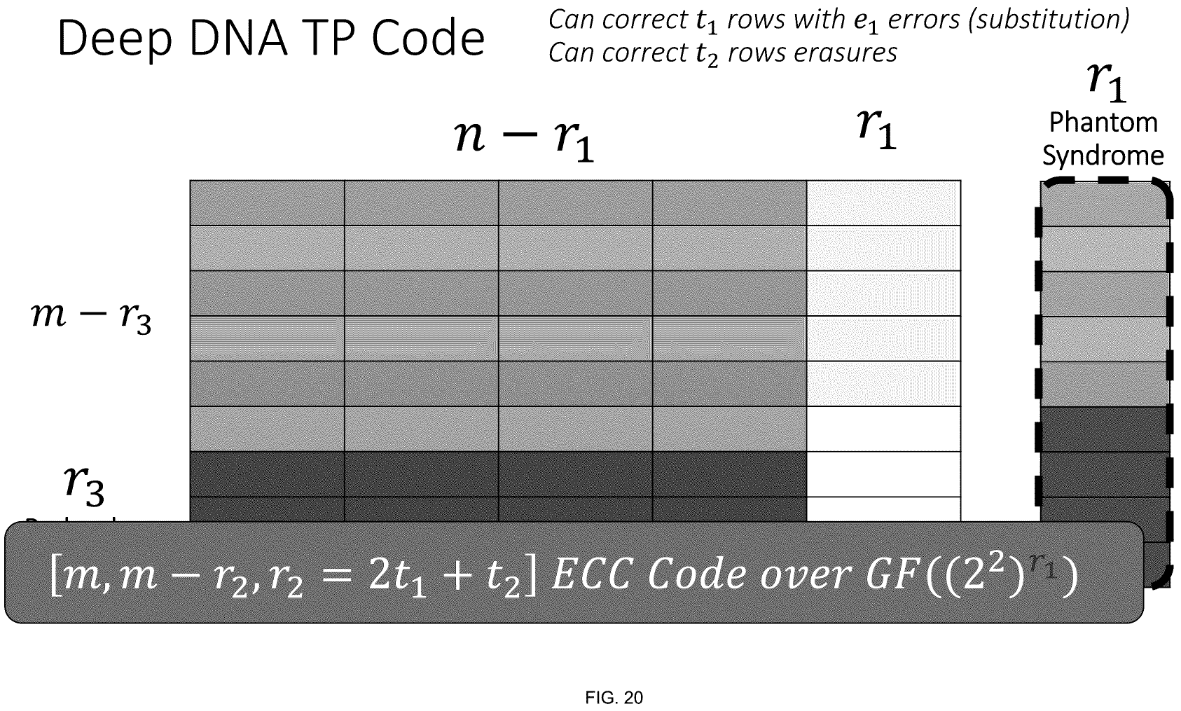

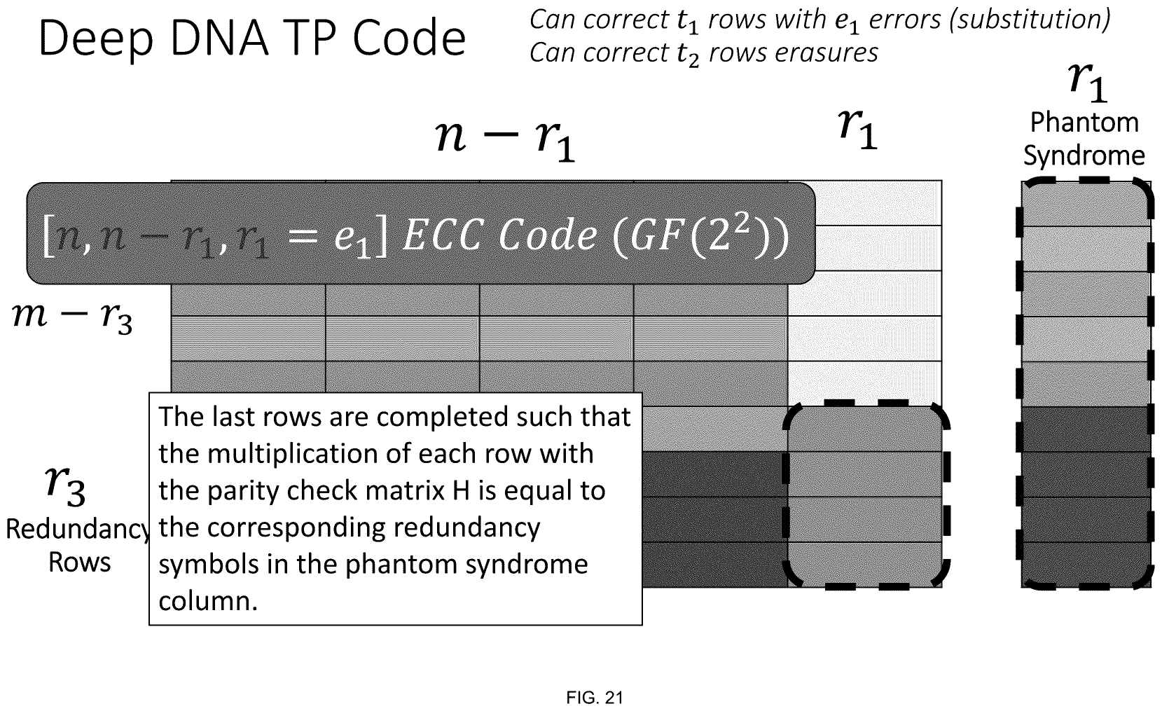

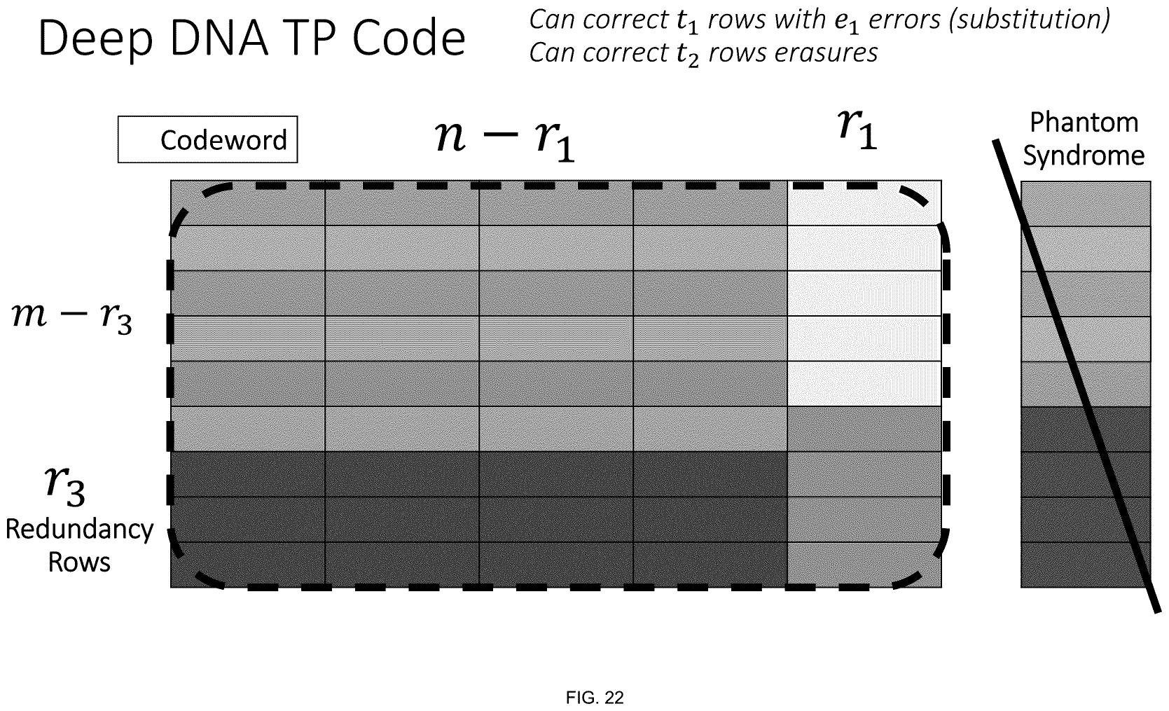

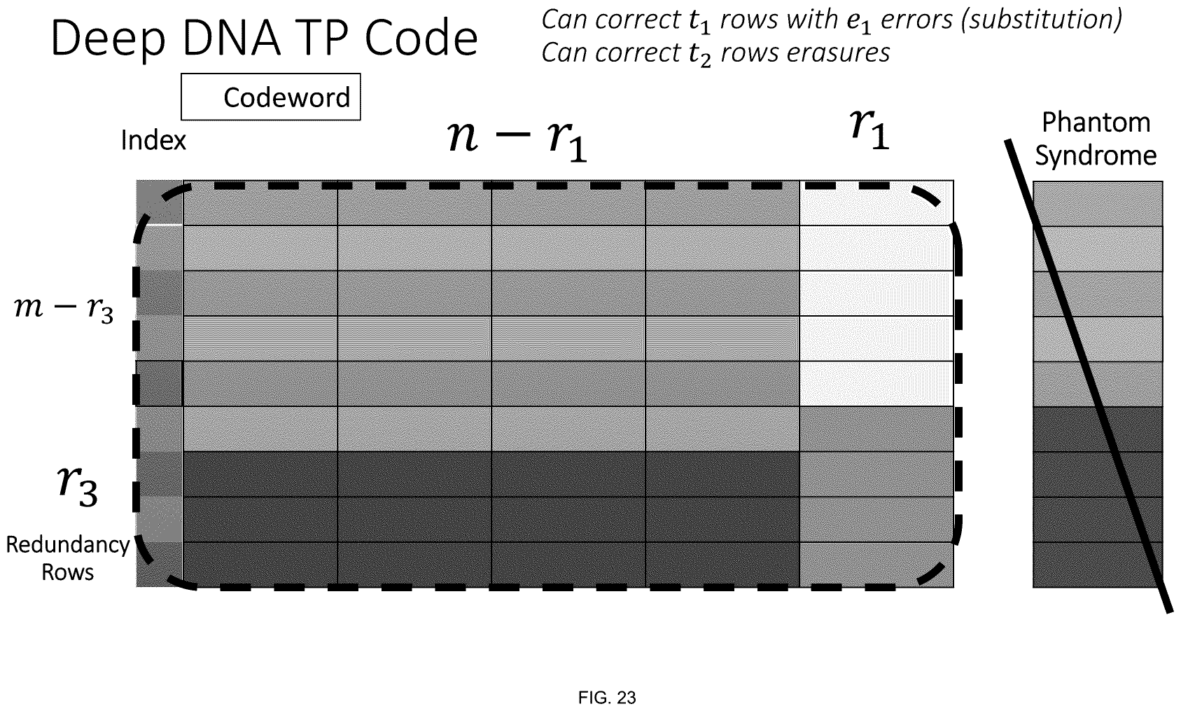

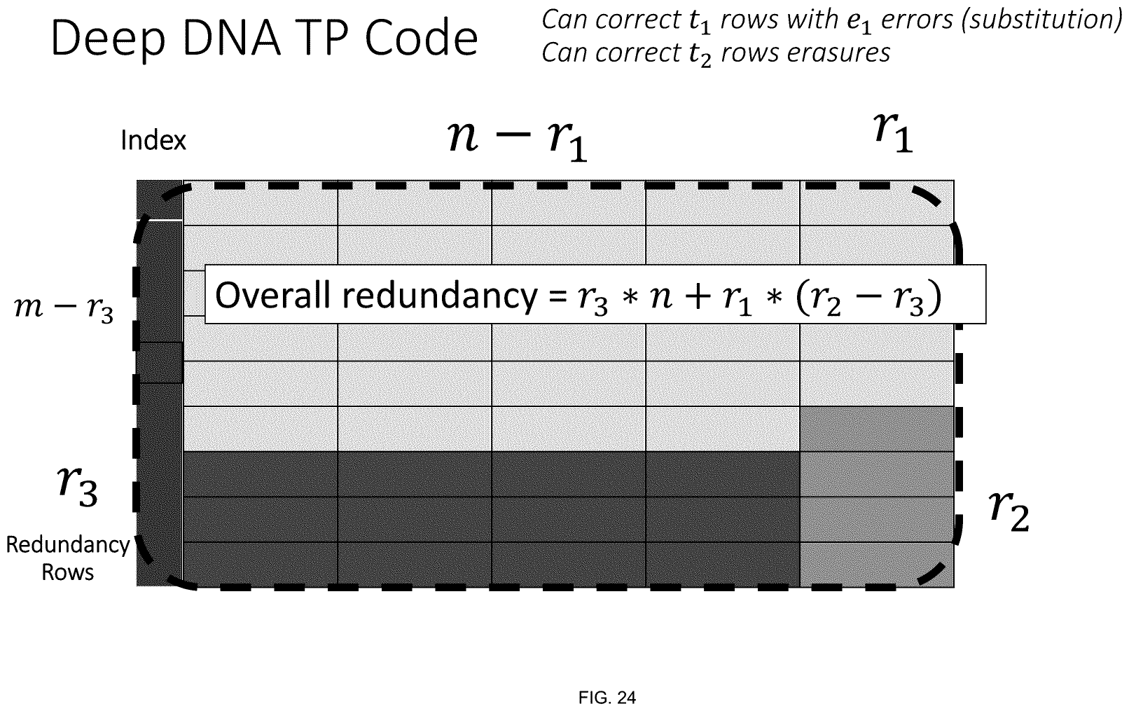

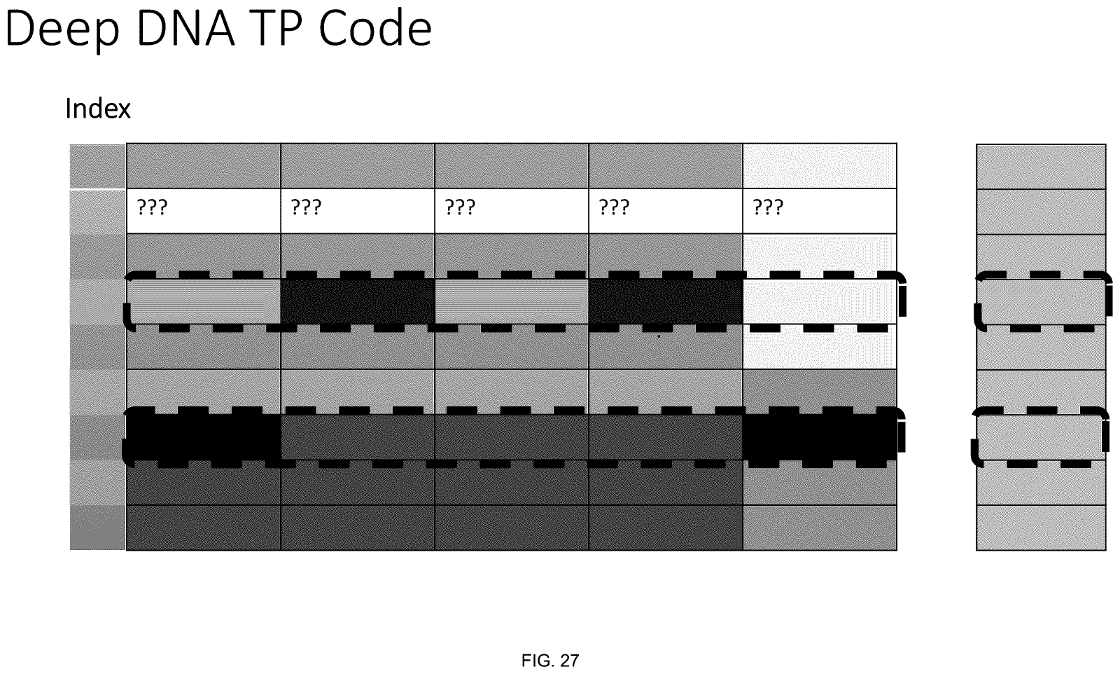

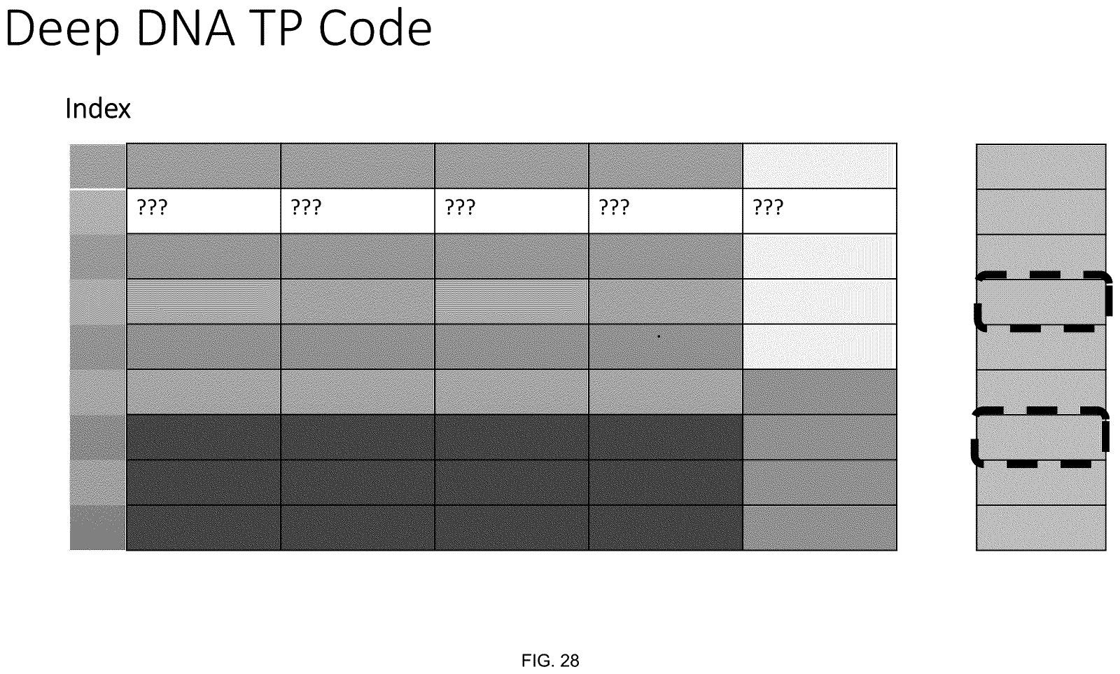

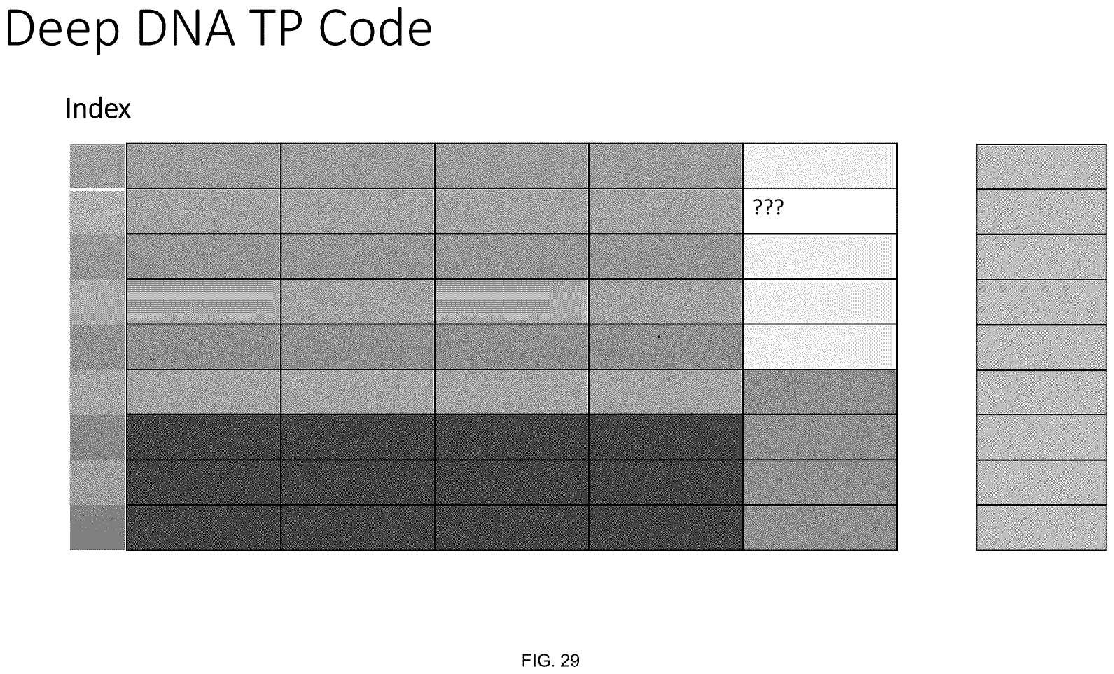

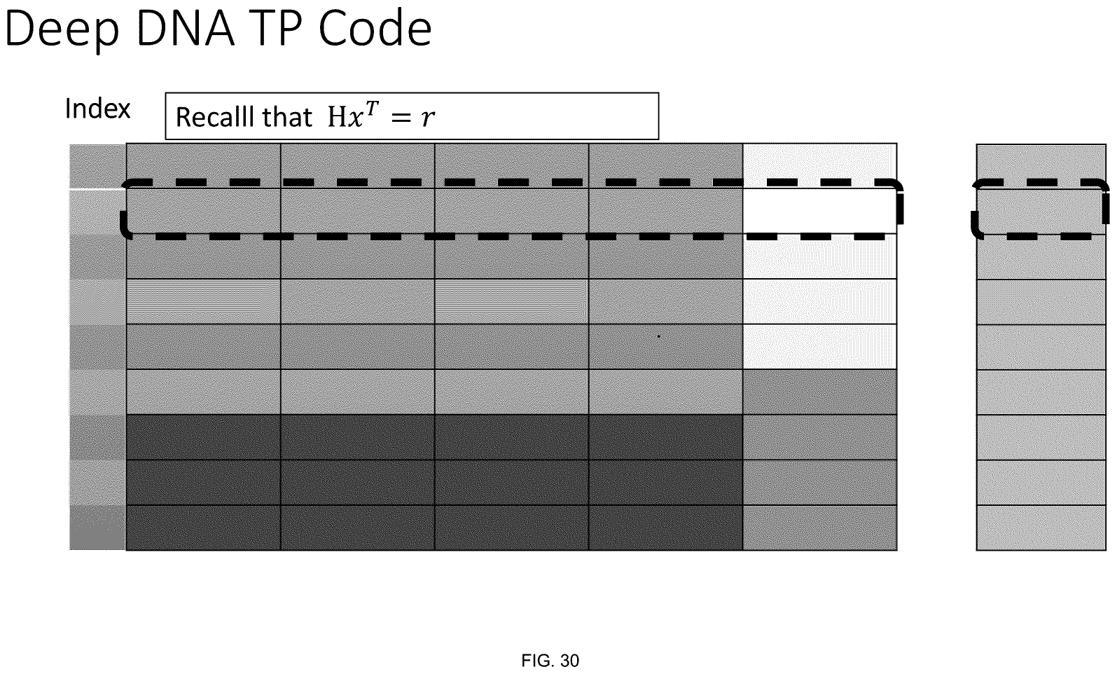

FIGS. 16-27 illustrates the following steps:
The binary information bits are written in the matrix and divided into rows of length n, and rows of length n−r_1, where n and r_1 are parameters of the code. (FIG. 16).
The short rows (of length n−r_1) are protected using a diagonal error-correcting code. Hence, r_3 short rows of redundancy are added to the matrix. (FIG. 17).
After the previous step, each of the binary rows is converted to alphabet of {A,C,G,T} (“bases”) using a constrained code, in which each block of bits is converted to block of bases. The output satisfies no long homopolymers (runs) and balanced GC-content. (FIG. 18).
The m−r_3 first long rows (of length n) are encoded with a systematic error-correcting code, and their syndrome are calculated using the parity check matrix H. The calculated syndrome are called “phantom syndrome” and they are not part of the stored codeword. (FIG. 19).
The phantom syndrome vector is encoded with an error-correcting code. (FIG. 20).
The last rows are completed such that the multiplication of each row with the parity check matrix H is equal to the corresponding redundancy symbols in the phantom syndrome vector. (FIG. 21).
It should be noted that the phantom syndrome vector is logic and is not stored in the system. (FIG. 22).
A predefined index is added to each row in the matrix, and the matrix with the indices is the codeword of the system. (FIG. 23).
The overall redundancy (excluding the indices) is r_3*n+r_1(r_2−r_3). (FIG. 24).
The confidence measure of the DNN is used to classify the reconstructed strands. (FIG. 25).
A demonstration of possible errors in the system. The second row was erased, and two symbols from the fourth and the sixth rows have errors. (FIG. 26).
Decoding process. First the phantom syndrome vector is calculated and using the error-correcting code of the phantom syndrome, the lost and erroneous syndromes can be corrected. (FIG. 27).
The corrected erroneous syndromes can be used to detect that the fourth and the sixth rows has errors. Using the corrected syndromes, the fourth and the sixth rows are corrected with the predefined error-correcting code. The corrected erroneous syndromes can be used to detect that the fourth and the sixth rows has errors. Using the corrected syndromes, the fourth and the sixth rows are corrected with the predefined error-correcting code. (FIG. 28).
The first n−r_1 symbols of the erased row can be corrected using the diagonal vertical error-correcting code that was defined on the rows. (FIG. 29).
The remaining erased symbol can be corrected using the corrected phantom syndrome with the matrix H of the code. (FIG. 30).

There may be provided systems, methods and a non-transitory computer readable media for reconstruction of data stored in a DNA storage system.

The following text refers to methods for simplicity of explanation.

FIG. 31 illustrates method 390 for estimating an information unit represented by synthetic DNA strands.

Method 390 includes (i) step 392 of sequencing the DNA strands to provide noisy copies of an encoded version of the information unit; wherein the information unit may include information unit elements; (ii) step 394 of neural network (NN) processing the multiple noisy copies by one or more NNs to provide a soft estimate of the encoded information unit; wherein the soft estimate may include estimated encoded information unit elements and an encoded information unit elements estimated confidence parameter; and (iii) step 396 of decoding the soft estimate of the encoded information unit to provide a prediction of the information unit.

The one or more NNs may include a first NN and a second NN, wherein the NN processing may include (i) processing the noisy copies by the first NN, (ii) processing an inverse-ordered version of the noisy copies by the second NN, and (iii) determining the soft estimate based on an output of the first NN and an output of the second NN.

The one or more NNs could have been trained using training simulated DNA strands.

The method may include one or more initial steps 391.

The one or more initial steps 391 may include at least one of:
Training the one or more NNs using training simulated DNA strands.
Receiving the trained one or more NNs.
Receiving the training simulated DNA strands.
Generation of the training simulated DNA strands. This may include executing a generation process that may include (i) obtaining training content; (ii) introducing errors to the training content to provide erroneous training content; and (iii) feeding to the erroneous training content to the at least one NNs. The introducing of errors may be executed based on error statistics of a combination of DNA synthesis and DNA sequencing.
Modeling the error statistics.
Generalizing the error statistics to provide expanded error statistics, wherein the introducing of the errors may include applying the expanded error statistics. Generalizing—adopting the statistics to cover more channels and/or more noise statistics—in order to cover combinations of DNA synthesis and DNA sequencing that differ from the learnt combination of DNA synthesis and DNA sequencing.

The encoded information unit may include encoded segments, each encoded segment is represented by a cluster of DNA strands that are noisy copies of the encoded segment, and wherein the soft estimate of the encoded information unit may include soft estimates of the encoded segments.

At least some of the clusters may be unknown.

The encoded segments may be without encoded segments inner-code.

Step 396 may include at least one of:
Classifying the estimated encoded segments into different classes based on the estimated confidence parameter associated with elements of the encoded segments.
Applying different decoding steps on encoded segments that belong to at least two classes of the different classes.
Differently decoding encoded segments that belong to different classes.
Ignoring encoded segments based on an estimated confidence parameter associated with the encoded segments.
Generating a binary version of the encoded segments.
Applying a DNA-flavor version of tensor-product decoding. The DNA-flavor version of tensor-product decoding is a tensor product decoding that is tailored based on properties of the DNA.
Performing constraint decoding.
Application a DNA-flavor version of tensor-product decoding as a part of error correction decoding.
Executing a DNA-flavor version of tensor-product decoding that may be associated with a DNA-flavor version of tensor-product encoding and may include: (i) writing a binary version of the information unit within a first region (A) of a first matrix and a second region (A′) of the first matrix; (ii) error correction encoding the binary version to provide redundancy bits and writing the redundancy bits in a third region (B) of the first matrix; (iii) applying a constraint code on content of the first region, second region and third region to provide first region quaternary content, second region quaternary content and third region quaternary content; (iv) applying a kernel (H) on first rows of the first matrix to provide a first shadow first matrix portion (C); wherein a part of each first row belongs to the first region and another part of each first row belongs to the second region; (v) error correction encoding a binary representation of the first shadow matrix portion to provide shadow matrix redundancy bits and writing the shadow matrix redundancy bits in a second shadow matrix portion (D); and (vi) calculating content of the fourth region so that a product of a multiplication of the kernel (H) by an i'th row of the first matrix will provide an i'th row of the shadow matrix.

FIG. 32 illustrates method 400 for estimating an information unit represented by DNA strands, the method may include: (i) step 402 of sequencing the DNA strands to provide copies of an encoded version of the information unit; wherein the information unit may include information unit elements; (ii) step 404 of neural network (NN) processing the multiple copies by one or more NNs to provide prediction; and (iii) step 406 of decoding the NN prediction of the encoded information unit to provide a reconstruction of the information unit.

FIG. 33 illustrates a method 410 for generating a training dataset, the method may include: (i) step 412 of obtaining content that was stored in DNA strands, the content was synthesized and then sequenced using a certain process; (ii) step 413 of determining error statistics related to the certain process; (iii) step 414 of obtaining training content; (iv) step 415 of introducing errors, based on the error statistics related to the certain process to the training content to provide erroneous training content; and (v) step 416 of training one more NN using the erroneous training content.

The method may be used to generate a large amount of training content based on a much smaller amount of the initial content stored in the DNA strands.

Step 415 may be executed based on error statistics of a combination of DNA strands synthesis and DNA strands sequencing.

Method 410 may include one or more initial steps 391.

The method may include modeling the error statistics.

The method may include generalizing the error statistics to provide expanded error statistics, wherein the introducing of the errors may include applying the expanded error statistics.

There is provided a method for estimating an information unit represented by simulated DNA strands, the method includes sequencing the simulated DNA strands to provide copies of an encoded version of the information unit; wherein the information unit comprises information unit elements; neural network (NN) processing the multiple copies by one or more NNs to provide prediction; and decoding the NN prediction of the encoded information unit to provide a reconstruction of the information unit.

There is provided a Robust, Efficient and Scalable Solution to Implement DNA-Based Storage Systems. Only simulated data was used to train the model. Better success rate than other SOTA algorithms. Outstandingly faster reconstruction. A tailor-made error-correcting code with higher information rate and a deterministic decoder is utilized.

The DNN Reconstruction—used Supervised Learning on Simulated Data. The method included an analysis of small sample of the data via SOLQC tool (2 precents of the noisy reads). Different synthesis and sequencing technologies and design constraints affects the error rates and their distribution. PCR amplification and the sequencing process affects the cluster sizes and their distribution. The method may be based on the SOLQC analysis the DNN is trained on simulated labeled data. Simulation is performed using the DNA Storalator. The simulated strands may be simulated randomly (in the design length). The training data is labeled, each noisy read is matched with the original randomly picked design.

The method used tensor product codes. This involves combining two constituent error correcting/detecting codes. The parity check matrix of the TP code is the Tensor Product of these two codes. Under a framework used by the inventors—the success rate was high—only a small fraction (less than 5%) had errors. Most of them have a small number of errors—substitutions, and the rest suffers from a large number of errors (and therefore are classified as erasures). TP codes allows higher error-correcting capability with less redundancy. Better than conventional inner/outer codes approaches.

The decoding was able to correct the phantom syndrome column using the ECC, we can detect the erroneous rows by their updates during the decoding process of the phantom syndrome column.
First we decode the TPC matrix using the redundancy of r_2 we can correct the lost phantom syndromes.
We then correct the row erasures using r_3.
Then, we use the r1 redundancy symbols to correct the columns substitutions.
Then, we correct the small right corner at the bottom of the matrix to using the rest of the symbols.

The Constraint Code

Our scheme satisfies the two main constrained that reduce sequencing and synthesis errors:
Balanced GC-Content (45%-55%).
Homopolymers' (runs) length is limited up to 4.

The mapping of blocks included:
Each block of bits is mapped to a 4ry block of symbols, with some redundancy symbols to satisfy the constraints.
The mapping is created during the encoding step and is used in the decoding process when correcting rows erasures.
The 4ry blocks are classified by their GC content and their prefix/suffix.
Then, they are selected by the encoder to maintain the constraints.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

It is appreciated that various features of the embodiments of the disclosure which are, for clarity, described in the contexts of separate embodiments may also be provided in combination in a single embodiment. Conversely, various features of the embodiments of the disclosure which are, for brevity, described in the context of a single embodiment may also be provided separately or in any suitable sub-combination.

It will be appreciated by people skilled in the art that the embodiments of the disclosure are not limited by what has been particularly shown and described hereinabove. Rather the scope of the embodiments of the disclosure is defined by the appended claims and equivalents thereof.

What is claimed is:

1. A method for estimating an information unit represented by DNA strands, the method comprises:
sequencing the DNA strands to provide noisy copies of an encoded version of the information unit; wherein the information unit comprises information unit elements;
neural network (NN) processing the multiple noisy copies by one or more NNs to provide a soft estimate of the encoded information unit; wherein the soft estimate comprises estimated encoded information unit elements and an encoded information unit elements estimated confidence parameter; and
decoding the soft estimate of the encoded information unit to provide a prediction of the information unit.

2. The method according to claim 1, wherein the one or more NNs comprise a first NN and a second NN, wherein the NN processing comprises (i) processing the noisy copies by the first NN, (ii) processing an inverse-ordered version of the noisy copies by the second NN, and (iii) determining the soft estimate based on an output of the first NN and an output of the second NN.

3. The method according to claim 1, wherein the one or more NNs were trained using training simulated DNA strands.

4. The method according to claim 1, comprising training the one or more NNs using training simulated DNA strands

5. The method according to claim 4, wherein the training simulated DNA strands are simulated by a generation process that comprises:
obtaining training content;
introducing errors to the training content to provide erroneous training content; and
feeding to the erroneous training content to the at least one NNs.

6. The method according to claim 5, wherein the introducing of errors is executed based on error statistics of a combination of DNA strands synthesis and DNA strands sequencing.

7. The method according to claim 6 comprising modeling the error statistics.

8. The method according to claim 6 comprising generalizing the error statistics to provide expanded error statistics, wherein the introducing of the errors comprising applying the expanded error statistics.

9. The method according to claim 1, wherein encoded information unit comprises encoded segments, each encoded segment is represented by a cluster of simulated DNA strands that are noisy copies of the encoded segment, and wherein the soft estimate of the encoded information unit comprises soft estimates of the encoded segments.

10. The method according to claim 9 wherein at least some of the clusters are unknown.

11. The method according to claim 9, wherein the encoded segments are without encoded segments inner-code.

12. The method according to claim 9, wherein the decoding comprises classifying the encoded segments to different classes based on the estimated confidence parameter associated with elements of the encoded segments.

13. The method according to claim 12, comprising and applying different decoding steps on encoded segments that belong to at least two classes of the different classes.

14. The method according to claim 12, comprising differently decoding encoded segments that belong to different classes.

15. The method according to claim 12, comprising ignoring encoded segments based on an estimated confidence parameter associated with the encoded segments.

16. The method according to claim 12, wherein the decoding comprises generating a binary version of the encoded segments.

17. The method according to claim 12, wherein the decoding comprises applying a DNA-flavor version of tensor-product decoding.

18. The method according to claim 17, wherein the decoding comprises constraint decoding.

19. The method according to claim 17 wherein the applying of the DNA-flavor version of tensor-product decoding is a part of error correction decoding.

20. The method according to claim 12, wherein the decoding comprises constraint decoding.

21. The method according to claim 17, wherein the DNA-flavor version of tensor-product decoding is associated with a DNA-flavor version of tensor-product encoding that comprises:
writing a binary version of the information unit within a first region (A) of a first matrix and a second region (A′) of the first matrix;
error correction encoding the binary version to provide redundancy bits and writing the redundancy bits in a third region (B) of the first matrix;
applying a constraint code on content of the first region, second region and third region to provide first region quaternary content, second region quaternary content and third region quaternary content;
applying a kernel (H) on first rows of the first matrix to provide a first shadow first matrix portion (C); wherein a part of each first row belongs to the first region and another part of each first row belongs to the second region;
error correction encoding a binary representation of the first shadow matrix portion to provide shadow matrix redundancy bits and writing the shadow matrix redundancy bits in a second shadow matrix portion (D);
calculating content of the fourth region so that a product of a multiplication of the kernel (H) by an i'th row of the first matrix will provide an i'th row of the shadow matrix.

22. A non-transitory computer readable medium for estimating an information unit represented by simulated DNA strands, the non-transitory computer readable medium stores instructions for: sequencing the simulated DNA strands to provide noisy copies of an encoded version of the information unit; wherein the information unit comprises information unit elements; neural network (NN) processing the multiple noisy copies by one or more NNs to provide a soft estimate of the encoded information unit; wherein the soft estimate comprises estimated encoded information unit elements and an encoded information unit elements estimated confidence parameter; and decoding the soft estimate of the encoded information unit to provide a prediction of the information unit.
